(19) United States
(12) Patent Application Publication
(10) Pub. No.: US 2026/0372042 A1
(43) Pub. Date: Nov. 19, 2026

(54) USING DIFFERENT LITHOGRAPHIC PROCESSES TO MANUFACTURE PREFERRED AND NON-PREFERRED WIRING DIRECTION LAYERS OF AN IC

(71) Applicant: D2S, Inc., San Jose, CA (US)

(72) Inventors: George Janac, Saratoga, CA (US); Akira Fujimura, Saratoga, CA (US)

(73) Assignee: D2S, Inc., San Jose, CA (US)

(21) Appl. No.: 19/651,582

(22) Filed: Apr. 17, 2026

Related U.S. Application Data
(60) Provisional application No. 63/806,279, filed on May 15, 2025.
(60) Provisional application No. 63/791,182, filed on Apr. 18, 2025.

(51) Int. Cl. H10W 20/00; G03F 7/00; G03F 7/20

(52) U.S. Cl. CPC H10W 20/067; G03F 7/0035; G03F 7/2004; G03F 7/70033; G03F 7/70341

(57) ABSTRACT

Some embodiments provide a novel method of manufacturing an integrated circuit (IC) wafer with a first set of non-preferred direction (NPD) wiring layers and a second set of preferred direction (PD) wiring layers above the first wiring layer set. The method uses a first lithographic technology type to manufacture wiring on the first wiring layer set. The method uses a second lithographic technology type that is less advanced than the first lithographic technology type to manufacture wiring on the second wiring layer set above the first wiring layer set. Each particular layer in the second wiring layer set is a PD wiring layer as more than 50% of the wiring on the particular layer is along a single PD of the particular layer.

### CLAIM OF BENEFIT TO PRIOR APPLICATIONS

This application claims benefit of U.S. Provisional Applications (1) 63/791,182, filed Apr. 18, 2026, and (2) 63/806,279 filed May 15, 2025. U.S. Provisional Applications 63/791,182 and 63/806,279 are incorporated herein by reference.

### BACKGROUND

An integrated circuit (“IC”) is a device that includes many electronic components, such as transistors, resistors, diodes, etc. These components are often defined on a semiconductor substrate and interconnected with metal wiring and vias to form numerous circuit components, such as gates, cells, memory units, arithmetic units, controllers, decoders, etc. An IC typically includes multiple layers of wiring and vias that interconnect its electronic and circuit components.

Electronic design automation (EDA) tools are used to define an IC design layout that specifies the overall design of the IC. One EDA tool is a placer that defines the position of the circuit components (e.g., cells) in the designed layout of the IC. After the circuit components are placed, one or more routers in the EDA process are used to define routes that specify the connections between the circuit components. The routes include vias that traverse between IC layers (e.g., device layers, routing layers, etc.) to connect pins, contacts and/or wiring on these layers. Routers typically define the routes in a metal stack composed of multiple routing layers and via layers between these routing layers. For some EDA tools, each layer in a metal stack includes metal layer and the via layer(s) to metal layer(s) above and/or below.

Most routers today use preferred direction, Manhattan routing. Under this technique, each layer has a preferred routing/wiring direction (e.g., a direction along which the majority of the wiring traverses on that layer. The two most common preferred directions used today are the two Manhattan directions, which are the horizontal and vertical directions. Also, it is common for the preferred direction of successive routing layers to change between the two Manhattan directions in many of the designs today.

Existing routers allow routes along non-preferred directions on each layer but penalize routes along the non-preferred directions on each layer to heavily bias the routes to traverse along the preferred directions. Other non-Manhattan and non-preferred direction routing techniques have been proposed, such as the X routing of Simplex Solutions, Inc., which allowed routing along preferred direction 45 degree as well as preferred direction horizontal and vertical directions. However, to date the predominant routing that is commercially used for ICs is the preferred direction, Manhattan routing.

After the routes are defined and the routes and overall IC design layout has been verified by verification tools of the EDA process, several masks are designed, verified and then fabricated. One or more lithographic processes use the masks to manufacture the ICs that implement the IC design layout. The routes and vias in the physical design result in wires and vias in the manufactured IC.

Three of the more advanced lithographic processes used today include EUV (Extreme Ultra Violet), 193i (193 nm immersion), and 193d (193 nm dry) options, with EUV being the most advanced followed by 193i. Some ICs are manufactured by using just one lithographic process. Other ICs are manufactured by using multiple lithographic processes. For such ICs, some fabrication companies can manufacture two different layers (with each layer including a metal/via layer pair) in the metal stack using two different techniques based on resolution and cost requirements, as the different lithographic processes have different costs. Today, EUV has one of the highest costs followed by 193i and then 193d. Each lithographic process also has a resolution limit. EUV today has one of the highest resolution limits followed by 193i followed by 193d.

Resolution limit can be further improved by multi-patterning. Multi-patterning uses two or more masks, and multiple additional steps for a single layer. In multi-patterning, the layout patterns are split in a way that minimizes conflicts in the layout graph. However, even multi-patterning has its practical limits imposed by manufacturing cost and wafer yield.

Cost difference between EUV and 193i/193d is very high. Increased resolution of EUV comes at the cost of much higher equipment and processing costs. Additionally, even though each metal layer can be viewed as a metal/via pair, masks and processing for the metal and via are separate. Lessening the number of layers needed for manufacturing an IC reduces the cost of the IC and improve the IC’s profit margin.

### BRIEF DESCRIPTION OF FIGURES

The novel features of the invention are set forth in the appended claims. However, for purposes of explanation, several embodiments of the invention are set forth in the following figures.

FIG. 1 illustrates an IC that is designed and manufactured using the omni-routing and optimized-lithographic processes of some embodiments.

FIG. 2 illustrates an example of an IC design that is produced by an omni routing process of some embodiments that only uses straight wire segments to define its routes for third and fourth wiring layers.

FIG. 3 illustrates an example of an IC design that is produced by an omni routing process of some embodiments that uses both straight wire segments and curvilinear wire segments to define its omni routes for third and fourth wiring layers.

FIG. 4 illustrates an example of an IC design that is produced by an omni routing process that explores and defines routes not only on the NPD third and fourth wiring layers but also on the available spaces on the first two PD wiring layers that are not consumed by Manhattan wiring.

FIGS. 5 and 6 present two examples illustrating that manufactured wires in an IC do not exactly match the corresponding routes in the physical designs of the IC.

FIG. 7 illustrates an example that shows that the curved wire segments that are manufactured to implement the purposefully defined curvilinear routes in an IC’s physical design more closely match the defined curvilinear routes than curved wire segments that are manufactured to implement piecewise linear routes.

FIG. 8 pictorially illustrates advantages of using NPD wiring layers.

FIG. 9 illustrates an example of a backside power delivery network.

FIG. 10 illustrates an example of a straight-line diagonal connection formed on an NPD metal layer.

FIG. 11 presents another example that illustrates the benefit of using omni-directional routing on one NPD wiring layer.

FIG. 12 illustrates a routing process of some embodiments that defines routes to connect a net list associated with a design of an IC.

FIG. 13 conceptually illustrates an overall routing process of some embodiments for defining routes for an IC design.

FIG. 14 conceptually illustrates a process of some embodiments for defining routes (i.e., detailed routes) for connections of an IC design.

FIG. 15 conceptually illustrates a process of some embodiments for selecting different routing models for connections to use to route the connections.

FIGS. 16A-B illustrate a set of options for routing model selection as well as the selection of specific routing models for specific connections.

FIG. 17 conceptually illustrates a process for performing static pin planning for a set of connections of an IC design.

FIGS. 18-19 illustrate two examples of pin protection performed for pins based on pin density and Gcell density.

FIG. 20 illustrates the definition of a partial route for a connection of two pins.

FIG. 21 illustrates an example connection of pins for which a partial route is defined.

FIGS. 22A-D illustrate different examples of pin protection removal performed during routing of two separate connections.

FIG. 23 conceptually illustrates a process of some embodiments for protecting candidate locations of different pins of connections.

FIG. 24 illustrates a two-stage example of pin protection performed for a net including pins.

FIG. 25 illustrates an example pin of a PD-designated connection for which different via stacks can be defined (either during or prior to routing of the connection involving the pin.

FIG. 26 illustrates an example set of grids used for at least a portion of a metal layer stack.

FIG. 27 illustrates an example IC manufactured using different sets of lithographic machines.

FIG. 28 illustrates an example IC with metal layers and buried power rails.

FIG. 29 illustrates two power deliver methods used on an IC.

FIG. 30 conceptually illustrates an example of one such process for designing and manufacturing an IC.

FIG. 31 conceptually illustrates a computer system with which some embodiments of the invention are implemented.

### DETAILED DESCRIPTION

In the following detailed description of the invention, numerous details, examples, and embodiments of the invention are set forth and described. However, it will be clear and apparent to one skilled in the art that the invention is not limited to the embodiments set forth and that the invention may be practiced without some of the specific details and examples discussed.

Some embodiments provide a novel method of manufacturing an integrated circuit (IC) with a first set of non-preferred direction (NPD) wiring layers and a second set of preferred direction (PD) wiring layers above the first set of wiring layers. The method uses a more-advanced first lithographic process (also called first lithographic technology) to manufacture wiring on the first set of one or more NPD wiring layers, while using a less advanced, second lithographic process (also called second lithographic technology) to manufacture wiring on the second set of one or more PD wiring layers. For instance, some embodiments use a more advanced, more expensive first lithographic process that uses EUV to manufacture finer pitch wiring on a few lower wiring layers (e.g., two or three wiring layers) and then transition to using a less advanced, less expensive second lithographic process that uses 193i or 193d to manufacture wider pitch wiring on several higher wiring layers.

A wiring layer is a PD wiring layer when more than a threshold amount (e.g., 50%, 75%, or 90%) of the wiring (also called interconnects, interconnect lines, wires or wire segments below) on that layer traverses along a single preferred direction (e.g., the horizontal direction, the vertical direction or a diagonal direction) of that layer. A wiring layer is an NPD wiring layer when it does not have a single preferred direction for more than a threshold amount of the wiring on that layer.

An IC’s design is defined by a physical design layout (also called physical design below) that typically includes one routing layer for each wiring layer of the IC. In some embodiments, the IC’s physical design is defined by a set of one or more physical design tools (e.g., by one or more routers) that define the wiring on the wiring layers in a way that biases the wires to traverse along the preferred direction of each PD wiring layer while not biasing the wiring on each NPD wiring layer towards traversing along a single preferred direction for that layer. For instance, to bias the wiring on a PD wiring layer to traverse along the preferred direction of that layer, the routers of some embodiments penalize any defined route segment (corresponding to a wire segment) that traverses along a direction that is not the preferred direction of that layer. Given that a router is commonly used to define wiring on the wiring layers in an IC design, the wiring layers in the IC design are also commonly referred to as routing layers, while the interconnect wires are commonly referred to as interconnects and/or routes.

In some embodiments, the first lithographic process (1) uses a more advanced type of lithographic technology than the second lithographic process, and (2) can produce smaller feature sizes for IC components (e.g., transistors, diodes, capacitors, resistors, etc.) than the second lithographic process. Examples IC component features that can be produced with smaller sizes with the first lithographic process include minimum transistor gate width, minimum wire width, minimum transistor size, etc. Examples of more advanced set of lithographic technologies used by the first lithographic process include more advanced light emanating technologies, optical technologies, etc.

By using the more advanced, first lithographic process to manufacture the wiring on the first set of NPD wiring layers and then using the less advanced, second lithographic process to manufacture the wiring on the second set of PD wiring layers, some embodiments produce thinner wires on the first set of NPD wiring layers of the IC while producing thicker wires on the PD wiring layers.

Some embodiments use a novel multi-direction omni routing process to define multi-direction omni routes on a set of one or more NPD wiring layers. On each NPD layer, the omni-routing process of some embodiments allows the route generation process (e.g., the path search for generating the route) to generate a route for a net on the layer by exploring multiple equally available routing directions on that layer (e.g., along two, four, eight, twelve, twenty-two, or any other number of equally allowable directions that are not penalized compared to each other on that layer). A net is a collection of nodes (e.g., pins or contacts) that need to be connected by a route. During a routing operation, a router defines a route for each net in a netlist, which is a list of one or more nets for each of which the router has to define a route to connect the nodes of the net.

The multi-direction omni routers of some embodiments do not penalize routing along multiple specific wiring directions (e.g., two, four, eight, nine, ten, eleven or more directions). In some of these embodiments, the multi-direction omni router does penalize routing along one or more wiring directions that are not in the set of non-penalized wiring directions. In some embodiments, the omni router (or an omni routing process) defines curvilinear routes and/or piecewise linear routes.

The exploration of multiple equally available (non-penalized) routing directions during the route-generation process allows the multi-direction routing process (also called NPD routing process) of some embodiments to define an omni route on a layer for a net, with this route making one or more direction changes on the layer along several equally available routing directions on the layer (e.g., along two, four, eight, twelve, twenty-two, or any other number of equally allowable directions that are not penalized compared to each other on that layer).

The flexibility to explore among several equally available routing directions on each NPD layer during the route generation of each net has several benefits. For instance, it allows the multi-direction omni routing process to reduce the number of vias used to change directions along the routes, increases the route density on each NPD routing layer, reduces the number of routes that have to traverse to a higher layer in order to be completed, and reduces the density of pin contacts that need to be defined on the higher wiring layers to ensure sufficient route connections to the pins.

These benefits, in turn, reduce the number of NPD wiring layers that have to be manufactured by using a more advanced, more expensive lithographic process (e.g., EUV lithographic process). In other words, these benefits allow the manufacturing process to transition earlier transitioning in the metal stack to the use of the less advanced, less expensive lithographic process(es) (e.g., 193i, 193d, etc.).

Hence, some embodiments use multi-direction omni routing on several NPD wiring layers to reduce the number of wiring layers that need to be manufactured by using a more advanced lithographic process, and transition earlier in the metal stack to using a less advanced lithographic process. In some embodiments, the use multi-direction omni routing on several NPD wiring layers also allows the IC to have a shorter metal stack (i.e., reduces the total number of wiring layers of the IC). In these manners, the use of NPD routing on IC layers that are manufactured using the more advanced, first lithographic process reduces the cost of the IC while improving its yield (e.g., by reducing the number of vias).

For some IC designs, the first set of NPD wiring layers in some embodiments is not the lowest set of wiring layers but is a set of wiring layers above the lowest metal layers. In some embodiments, the lowest metal layers are Manhattan layers as the majority of the interconnect (e.g., poly and metal wiring) on these layers are along Manhattan directions (e.g., horizontal and vertical directions). The Manhattan direction interconnects on these layers (1) define the devices (e.g., transistors), and/or (2) connect the devices to form circuit components (e.g., Boolean gates), cells, macro-cells and IP blocks.

For instances, in some designs, the design layer and one or more of the lowest metal layers are Manhattan layers that use a Manhattan grid and Manhattan interconnect directions to define the devices (e.g., transistors, resistors, etc.) and to interconnect the devices to form larger circuit components, such as logic gates, cells, macro cells, IP blocks, etc. However, even for some such designs, the router of some embodiments uses multi-direction omni routing on whatever space that is available for routing on the lowest metal layers, which are otherwise PD Manhattan layers in these embodiments.

In some embodiments, each route on an NPD wiring layer only uses piecewise linear straight wire segments that traverse along one or more available wiring directions of that layer, with no direction being the single predominant preferred direction of the layer. Some embodiments use all-angle wiring on an NPD wiring layer. Hence, in these embodiments, the piecewise linear (PWL) wire segments of a route can traverse along any direction as all angles of wiring are allowed on the NPD wiring layer. Other embodiments do not employ all-angle wiring on any NPD layer but rather provide a finite number of allowable wiring directions on each NPD layer (e.g., provide two, four, eight, twelve, twenty-two, or other number of equally allowable directions on the NPD layer).

In addition to piecewise linear straight segments, some embodiments allow a route on an NPD wiring layer to be a curvilinear route that has one or more curved segments. A curvilinear route on an NPD wiring layer in some embodiments can have one or more piecewise linear segments as well. Other embodiments do not allow the routes to have curvilinear segments on any NPD layer or on one or more of the NPD layers.

In this document, a curvilinear route is a route that has at least one curved segment (also called curved edge), while a non-curvilinear route is a route that has no curved segment. An example of a non-curvilinear route is a PWL route that is only formed by straight line segments (also called straight line edges), e.g., line segments that can be defined by reference to a first degree polynomial equation, such as y=mx+b, where x and y are coordinates along the line, m is the slope, and b is the y-intercept. A curved segment (also called curved edge) of a curvilinear route in some embodiments is an edge that can be defined by reference to any one of several common ways to define a curve, such as a second degree or higher polynomial equation, a Bezier function, a spline function (B-spline function), etc.

The multi-direction omni router of some embodiments limits the length of most or all routes on an NPD layer to be below a certain size. This is because routes are manufactured on lower wire layers are thinner wires, which have a higher resistance and hence suffer signal degradation when traversing longer distances. Hence, some embodiments use the NPD wiring layers for only or mostly shorter local connections, while mostly using the second set of PD wiring layers (above the first set of NPD wiring layers) for longer connections.

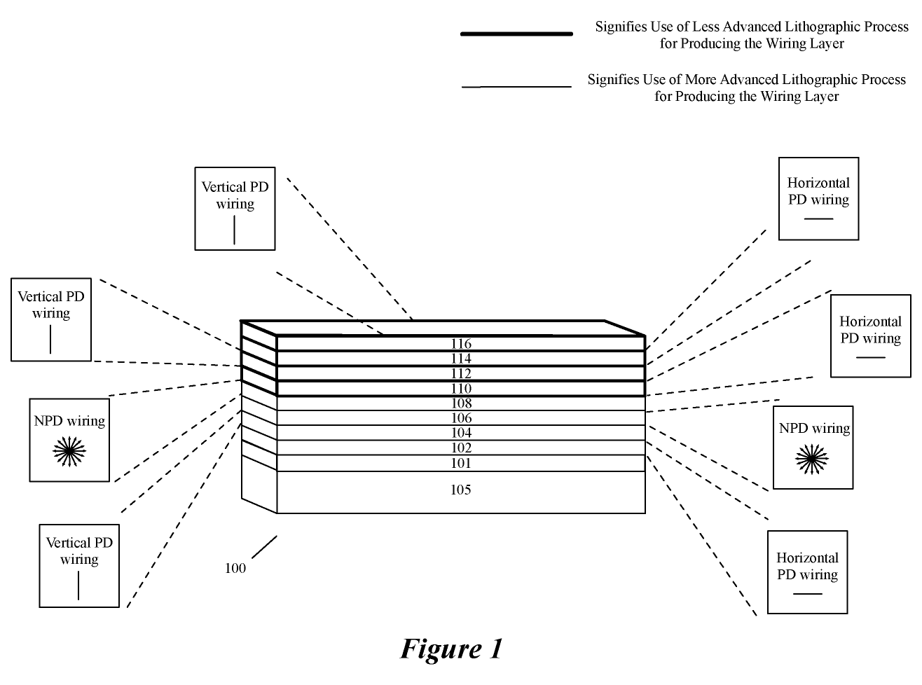

FIG. 1 illustrates an IC 100 that is designed and manufactured using the omni-routing and optimized-lithographic processes of some embodiments. Specifically, a multi-direction omni-routing process is used to define routes on several lower wiring layers, one or more of which are NPD wiring layers. These lower wiring layers of the IC, along with the device layer(s), are manufactured using a more-advanced first lithographic technology process, while a less advanced, second lithographic technology process is used to manufacture wiring on higher wiring layers above these lower wiring layers, as further described below. In some embodiments, these higher wiring layers are PD wiring layers, as further described below.

As shown, the IC 100 includes a substrate 105, one or more device layers 101 on which devices are defined, and multiple wiring layers (also called metal layers) on which wires are defined to interconnect the devices and the circuits that are formed by interconnecting the devices. The substrate 105 provides a surface on which the devices of the IC 100 are defined. The substrate 105 in some embodiments is a semiconductor (e.g., silicon) wafer.

A device layer 101 of an IC is a layer on which one or more devices of the IC are defined. Examples of such devices include transistors, diodes, capacitors, and resistors. The device layers for some ICs include the top surface of the substrate in some embodiments. For instance, 2-dimensional (2D) field-effect transistors (FETs), known as planar FETs, have their source and drain defined on the top surface of the substrate. Conjunctively, or alternatively, the device layer in some embodiments includes one or more layers defined on top of the substrate surface. For instance, ICs have one or more such device layers when 3-dimensional (3D) field-effect transistors (FETs), such as fin FETs (FinFETs), gate-all-around FETs (GAAFETs), and complementary FETs (CFETs), are defined on the ICs. 3D FETs have their source, drain and gates defined on device layers that are defined above the semiconductor substrate.

The wiring layers 102-116 include the wiring that connects the devices to form circuits (such as gates and cells) and then connects the circuits to form larger circuits (such as macro cells, IP blocks, etc.). For instance, in some embodiments, numerous electronic components (e.g., active components, like transistors and diodes, or passive components, like resistors and capacitors) are defined on the IC substrate and the device layer(s), and these electronic components are connected to each other through interconnect wiring on the wiring layers (e.g., layers 102-116 of IC 100) to form numerous microcircuits (e.g., Boolean gates) and/or larger circuits (e.g., functional blocks).

As such, the wires on the wiring layers are defined to electrically connect circuit nodes (e.g., points, contacts, terminals, or regions of a circuit element or between two circuit elements of circuits) in order to form electrical components (e.g., transistors, diodes, etc.) and circuits. When a connection traverses multiple IC layers to connect two or more nodes in a component or a circuit, the interconnects/wires on different layers are connected through one or more vias (not shown) in order to establish a contiguous electrical connection that is formed by the wires that traverse the different metal layers and the via(s). A via in some embodiments is a z-axis connection that traverses in a direction perpendicular (in a z-axis direction) to the IC layer surfaces, which are typically defined by x- and y-axes. Such a via traverses in the z-axis between IC layers (e.g., device layers, wiring layers, etc.) to connect two IC components (such as pins, contacts and/or wiring) on the IC layers

In the example of FIG. 1, the wiring layers of the IC 100 include (1) first and second PD wiring layers 102 and 104 each with a preferred Manhattan wiring direction, (2) third and fourth NPD layers 106 and 108 each of which is an NPD wiring layer without a single preferred direction for its wiring, and (3) the fifth through eight PD wiring layers 110-116, each with a single preferred wiring direction.

As the first, second, and fifth through eight layers 102, 104, and 110-116 are PD wiring layers, more than a predominant amount of wire segments (e.g., more than 90% or 95% of the wire segments) on each of these layers 102, 104, and 110-116 traverse along the PD of that layer. Conversely, as the third and fourth layers 106 and 108 are NPD wiring layers, neither of these layers 106 and 108 has a single preferred direction (e.g., the horizontal direction, the vertical direction, or a diagonal direction) that contains the predominant amount (e.g., more than a particular threshold amount, such as 90%) of the wire segments that traverse on that layer. As such, no preferred wiring direction exists on either the third layer 106 or the fourth layer 108.

In some embodiments, the set of one or more device layers 101 is also considered to be Manhattan layers as the devices, and the circuits (e.g., gates, cells, IP blocks, etc.) defined with these devices, are designed along a Manhattan grid and are defined using Manhattan directions (e.g., have their polysilicon or other interconnect for forming devices laid out in one of the two Manhattan directions).

In some embodiments, the PD for the wiring between adjacent PD wiring layers (e.g., between first and second layers, and between adjacent pairs of layers in the fifth to the eight wiring layers) alternate so that no two neighboring PD wiring layers have the same preferred direction. For instance, as shown in FIG. 1, the first and second PD wiring layers 102 and 104 have orthogonal preferred directions (e.g., horizontal and vertical). Also, in some embodiments, the PD for each of the other PD wiring layers 110-116 is also along one of the two Manhattan directions. In other embodiments, the PD for the first two wiring layers 102 and 104 are Manhattan directions, but one or more of the wiring layers after the fourth wiring layer have a diagonal preferred direction (e.g., the seventh and eight wiring layers 114 and 116 have +45 and -45 degree PD wiring in some embodiments).

The IC 100 is manufactured by using a more advanced first lithographic process (e.g., EUV) to produce the device layer(s) and the first four metal layers of the IC 100, while using a less advanced second lithographic process (e.g., 193i) to produce the fifth to eight metal layers. Also, in some embodiments, the physical design of the IC 100 is generated by using one or more multi-direction, omni routing processes to define the routes (that correspond to the wire segments) on the third and fourth NPD wiring layers 106 and 108.

In several embodiments described below, the multi-direction omni routing process (also called NPD routing process) also tries to define routes on any space that is available for routing (e.g., the space that is not used for defining the devices) in the design of the first and second metal layers 102 and 104. Hence, while being PD Manhattan layers, the first two metal layers 102 and 104 in these embodiments might have multi-direction omni wiring defined by the omni routing process in the available space on these layers (e.g., the space that is not used for defining the devices). In other embodiments, the multi-direction omni routing process does not define omni-direction routes on either of the first two wiring layers 102 and 104 and only defines such routes on the third and fourth wiring layers 106 and 108.

As the more advanced, first lithographic process is used to manufacture the wiring on the lower layers 101-108 and the less advanced, second lithographic process is used to manufacture the wiring on the fifth and higher metal layers 110-116, the IC 100 has thinner wires on the on the lower layers 101-108 and thicker wires on the higher layers 110-116. In some embodiments, the IC 100 with its NPD wiring layers enjoys other benefits as well, which will be described further below.

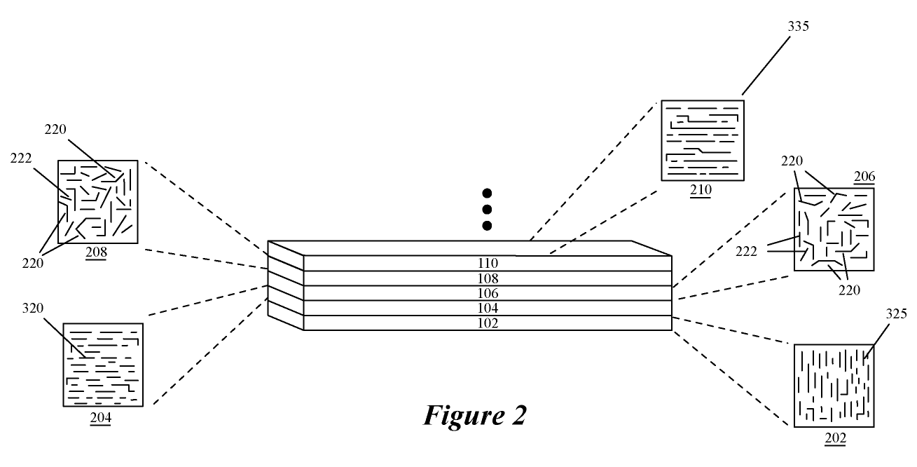

In some embodiments, the omni routing process defines routes with curvilinear and straight piecewise linear (PWL) edges, while in other embodiments the omni routing process only defines routes with straight PWL edges. For the IC 100, FIG. 2 illustrates an example of an IC design that is produced by an omni routing process of some embodiments that only uses straight PWL wire segments to define its routes for third and fourth wiring layers 106 and 108.

The illustrated portion of this IC design includes the wiring layer designs 202-210 for the first through fifth wiring layers 102-110. As shown, the third and fourth wiring layer designs 206 and 208 for the third and fourth NPD wiring layers 106 and 108 have several multi-direction omni routes 220 each of which changes directions one or more times. Also, each multi-direction omni route on the third or fourth wiring layer is composed of two or more straight edges that traverse along that the directions that are available on that layer to the omni routing process. The third and fourth wiring layers 106 and 108 also include many single-segment routes 222, i.e., routes that are each formed by one wire segment. As shown, these single-segment routes 222 are not restricted to only the Manhattan directions, as they can traverse along any wiring direction that is available on that layer to the omni routing process.

In some embodiments, the omni routing process use all-angle wiring on the NPD wiring layers 106 and 108, and hence the PWL wire segments of a route on the third or fourth wiring layer can traverse along any direction as all angles of wiring are allowed for routing on this layer. In other embodiments, the omni routing process does not use all-angle wiring on the NPD wiring layers 106 and 108, but rather defines its routes on each of these two layers 106 and 108 only along a finite number of allowable wiring directions (e.g., along two, four, eight, twelve, twenty-two, or other number of equally allowable directions) that are available for omni routing on each of these layers. Like all routes, a route (e.g., a multi-direction omni route) defined by the omni routing process of some embodiments can change wiring layers through the use of one or more vias in order to complete the connection between nodes (e.g., pins, etc.) that the route connects.

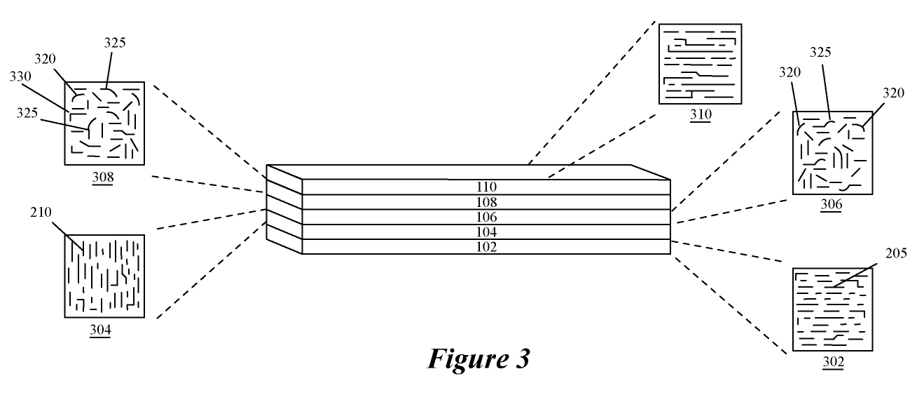

In addition to straight PWL segments, the omni routing process of some embodiments can define an omni-route on the NPD wiring layers 106 and 108 to have one or more curved segments. For the IC 100, FIG. 3 illustrates an example of an IC design that is produced by an omni routing process of some embodiments that uses both straight PWL wire segments and curvilinear wire segments to define its omni routes for third and fourth wiring layers 106 and 108.

The illustrated portion of this IC design includes the wiring layer designs 302-310 for the first through fifth wiring layers 102-110. As shown, the third and fourth wiring layer designs 306 and 308 for the third and fourth NPD wiring layers 106 and 108 have several curvilinear routes. Some of these curvilinear routes include only one curved segment on each of these layers. Examples of these single-segment curvilinear routes are routes 320. Other curvilinear routes on the third or fourth wiring layer include multiple segments, with one or more of these segments being curved. Examples of such multi-segment curvilinear routes are routes 325.

In this document, a curvilinear route is a route that has at least one curved segment (also called curved edge), while a non-curvilinear route is a route that has no curved segment, as mentioned above. In some embodiments, a route has two or more segments when the route has one or more points along its path where the slope of the route (i.e., its derivative, if viewing the plane of the layer as x-y axes) changes its functional expression. A multi-segment PWL route is a route segment that has multiple linear segments, and two or more of those segments are expressed by two or more differing functions. A multi-segment curvilinear route is a route segment that has multiple segments, two or more of these segments are expressed by two or more differing functions, and at least one of the functions is a nonlinear function, such as any one of several common functions used to define a curve (e.g., a second degree or higher polynomial equation, a Bezier function, a spline function (B-spline function), etc.).

As further shown in FIG. 3, the third and fourth wiring layer designs 306 and 308 for the third and fourth NPD wiring layers 106 and 108 also have several PWL routes that are formed by one or more straight segments. These PWL routes do not have any curved segments. On each of these layers 106 and 108, some of the PWL routes of FIG. 3 are multi-direction omni routes 330 that change directions one or more times to traverse along one of the available routing directions of their respective layers, while other PWL routes of FIG. 3 are formed by just one wire segment that traverses along one of the available wiring directions that is available on it respective layer.

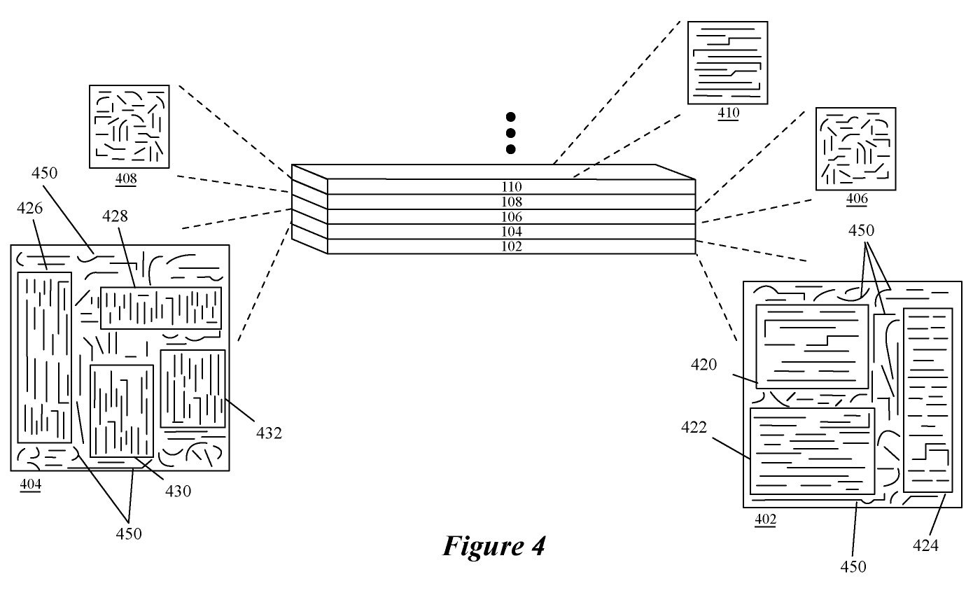

In the two examples illustrated in FIGS. 2 and 3, the omni routing process does not try to define multi-direction omni routes on the first two PD wiring layers 102 and 104. FIG. 4 illustrates an example of an IC design that is produced by an omni routing process that explores and defines routes not only on the NPD third and fourth wiring layers 106 and 108 but also on the available spaces on the first two PD wiring layers 102 and 104 that are not consumed by Manhattan wiring that is used to define devices, smaller circuits (such as gates, flip-flops, inverters, standard cells), larger circuits (e.g., macro cells, etc.), and IP blocks.

The illustrated portion of this IC design of FIG. 4 includes the wiring layer designs 402-410 for the first through fifth wiring layers 102-110. As shown, the omni routing process results in the IC design of FIG. 4 having numerous multi-direction routes on each of the lower PD wiring layers 102 and 104, as well as on the NPD wiring layers 106 and 108. Specifically, in the physical design 402 and 404 of the first two PD wiring layers 102 and 104, FIG. 4 illustrates several regions 420-432 that are consumed by Manhattan only routes. It also illustrates numerous curvilinear and multi-direction routes 450 that are defined by the omni routing process between these Manhattan only regions 0420-432.

Like the omni routes on layers three and four, some of the routes defined by the omni router on the first two layers 102 and 104 are curvilinear routes with one or more curved segments plus another segment, while other such defined routes are multi-direction omni routes composed of two or more straight edges that traverse along wiring directions that are available in the available-routing space between the regions 420-432. Also, like the omni routes on layers three and four, the omni routes on the first two layers 102 and 104 also include single segment curvilinear routes and single segment straight routes formed by a single wire segment traversing along one of several allowed wiring directions that is available for routing in the available-routing space between the regions 420-432.

Multi-direction wiring on the lower layers can be used by any type of ICs, such as ICs that use bulk CMOS, FinFET, GAAFET, or CFET transistors. For these different transistor styles, there are different standard cell layouts and device layers that affect how much available space there is for multi-direction wiring on the lower wiring layers. Moreover, as further described below, the power delivery network of these ICs also has a major impact on how much multi-direction wiring can be used on the lower wiring layers.

In an IC, standard cells are often laid out in horizontal rows or vertical columns. Also, large macro cells and I/O (Input/Output) cells that are used for off chip communication, are also often placed in horizontal rows or vertical columns. Standard cells, macro cells and I/O cells need to connect to wire segments and vias like all other circuit components. Moreover, all cells and circuit components are formed by transistors (e.g., CMOS transistor, FinFETs, GAAFETs, or CFET), which typically have a Manhattan structure (i.e., are Manhattan devices) as these transistors typically have the direction of their gates perpendicular to the direction of the drain-to-source connections.

Circuit components and cells contain pins that define the points where connections to components and cells are made. In some embodiments, pins of circuit components and cells are designed to be connected to in a Manhattan manner, i.e., along a vertical or horizontal axis of the IC. In some embodiments, the Manhattan connections to the pins are made on the device layer or one or two layers above the device layer. The router of some embodiments generally respects making Manhattan (i.e., vertical or horizontal) connections to the pins of the circuit component and cells. However, as space allows, the router of some embodiments uses a Manhattan via "nail head" on one layer as part of a via that then connects through to a non-Manhattan via nail head on a non-Manhattan layer above, in order to improve connection density.

Cells are typically composed of interconnected transistors. The cells themselves have connections that can block metal0, metal1, and metal2. On these layers, the blocking effect of the cells depends on the cell size, cell logic, and cell complexity. For instance, standard cells typically use the fewest resources. Simple cells can be implemented only with metal0 and metal1 wires. More complex cells may use metal2 to make internal connections for clocks, set, reset, and to strap across the cell.

For a standard cell, there can be some room for multi-direction routing on metals layers 0-2 in the region encompassed by the standard cell. Macro cells (e.g., SRAMs, ROMs, DRAMs, etc.) in some embodiments use layers up to metal layer 4 to implement internal routing connections. For multi-direction routing, macro cells in some embodiments leave some resources within their cell area on metal layers 0-2 and more resources on metal layers 3 and 4. I/O cells and analog cells can use the entire metal routing stack for connections and to protect sensitive internal nodes and thereby can block the entire cell area for use for multi-direction routing.

Standard cells can be sized to contain any number of gate pitches and tracks. In the direction of the device gates, there is the gate pitch which in this document is referred to as the CGP (Contacted Gate Pitch). The cell width can be any number of gate pitches, from one to N, based on the operation performed by the cell. Typically, the cell width is in the direction perpendicular to the cell row. The track pitch is in the direction of the row. The cell height is defined by the size of the transistors. Today it is common to have anywhere from 3 to 14 track pitches running along the direction of the cell row.

Each standard cell in the cell row needs to be provided with power supply connections. Rails for power supply and ground in some cases run in the direction of the cell row. The power rails in general, though not always, are at the top and bottom of the standard cell row. Power delivery to the rows affects how efficiently the multi-direction routing can perform as the rails create natural blockages to routing. As further described below, power routing styles are different in different embodiments.

Even when a wiring layer or a region in a wiring layer has a preferred wiring direction, the routing processes of some embodiments allow route segments to be defined along non-preferred directions but penalize such route segments sufficiently to bias against their use. This biasing results in the infrequent generation of non-preferred direction route segments, most often for only short jogs, such as short vertical or diagonal direction jogs on a horizontal PD layer or region, or short horizontal or diagonal direction jogs on a vertical PD layer or region. Examples of such NPD jogs are illustrated in FIGS. 2, 3, and 4.

The curvilinear routes that are defined in an IC design produce curved wire segments in a manufactured IC that implements the IC design. Curved wire segments, however, are also inadvertently produced today in some ICs because of manufacturing limitations. It is important to differentiate purposefully manufactured curvilinear wire segments that implement purposefully defined routes produced by a router in an IC’s physical design from inadvertently manufactured curved wired segments that result due to manufacturing limitations in some of the ICs manufactured today.

Routes that have short jogs or direction changes on a wiring layer can result in curved wire segments on the IC as a result of manufacturing limitations. This is because manufacturing limitations can result in a curved segment at each juncture of two segments of a multi-segment route (i.e., at any location where a multi-segment route changes directions) on one wiring layer. Accordingly, because of manufacturing limitations, the manufactured wires of ICs in some embodiments do not exactly match the corresponding routes that routers specify in the physical designs of the IC.

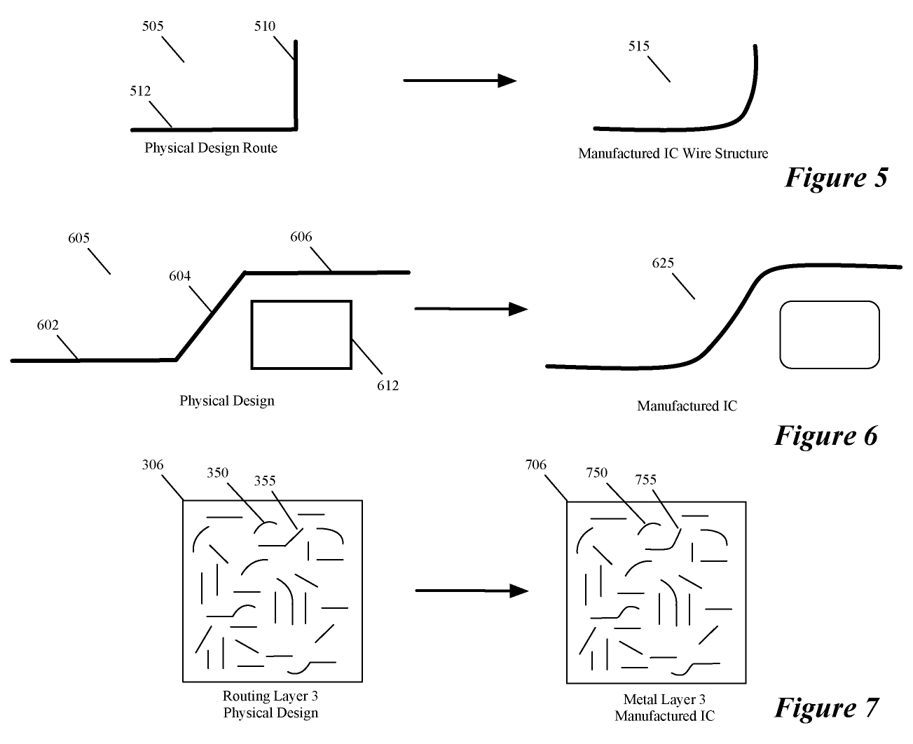

FIGS. 5 and 6 present two examples that illustrate this. In the example of FIG. 5, one route 505 in a physical design has two segments 510 and 512 that traverse along two different directions on one wiring layer. The second segment 510 is a short vertical jog. The IC manufacturing process cannot produce two wire segments that match the abrupt change of direction in the two route segments. Hence, as shown, the manufactured IC has a curve in the wire structure 515 that implements the route segments 510 and 512 in the physical design of the IC.

FIG. 6 illustrates a physical design with a three-segment route 605 that has two horizontal segments 602 and 606 and one diagonal segment 604 between these two segments 602 and 606. In this example, the route has the diagonal segment so that it can bend around an obstacle 612 in the physical design. The IC manufacturing process cannot exactly replicate the abrupt change of directions between the first and second route segments and between the second and third route segments. Hence, as shown, the manufactured IC 625 has a curve in the wire segment 615 that implements the route segments 602, 604 and 606 in the physical design of the IC.

As shown in FIGS. 5 and 6, the difference between the ideal shape of the IC design routes and these route’s corresponding wired connections in the manufactured IC is often the smooth curved edges that are produced in the wire connections at the locations that correspond to change-of-direction junctures in the multi-segment routes. These change-of-direction junctures can be for short or long jogs or can be for allowing the routes/wires to bend around another component (such as the example illustrated in FIG. 6).

The inadvertent manufacturing of curved wire segments due to manufacturing limitations today is different than the purposefully manufactured curved wire segments that are manufactured to implement the purposefully defined curvilinear routes in an IC’s physical design. This is because the purposefully manufactured curved wire segments match much more closely the curvilinear routes for which they are manufactured than the curved wire segments that are produced today due to limitations in manufacturing change of directions on a metal layer for routes that are defined through straight line segments.

FIG. 7 illustrates an example that shows that the curved wire segments that are manufactured to implement the purposefully defined curvilinear routes in an IC’s physical design more closely match the defined curvilinear routes than curved wire segments that are manufactured to implement PWL routes. Specifically, this figure presents a side-to-side comparison of (1) the idealized routes on the third routing layer 306 in the physical design illustrated in FIG. 3, and (2) the wired connections that are manufactured on the third wiring layer 706 of an IC that is manufactured to implement this physical design.

As shown, the manufactured curved wires (such as wires 750) on the third wiring layer more closely match the corresponding curvilinear routes (such as routes 350) on the third routing layer 306. On the other hand, the manufactured curved wires (such as wires 755) on the third wiring layer are more different than their corresponding PWL routes (such as routes 355) on the third routing layer 306.

As illustrated in the examples of FIGS. 2-4, the lower wiring layers that are manufactured with the more advanced first lithographic process (e.g., EUV) in some embodiments typically have shorter routes in the physical design and shorter wire connections on the manufactured IC. As shown, longer routes in the physical design and longer wire connections on the manufactured IC are typically defined for and manufactured on the higher wiring layers that are produced through the less advanced second lithographic process. One reason for this is that the wires that are produced by the more advanced first lithographic process have smaller widths and hence have higher resistance. Another reason is that longer routes on lower layers can often block other routes being formed on the lower layers.

Because of these issues, the routing processes of some embodiments bias or constrain the routing to define shorter wires on lower wiring layers that are manufactured with the more advanced, first lithographic technology (e.g., EUV). For instance, the omni-routing process of some embodiments uses such biasing or constraints to ensure that the route generation (e.g., the path search of the routing process) does not produce any routes (e.g., does not identify any route paths), or does not produce many routes, on the NPD wiring layers 106 and 108 that are longer than a threshold length. When the omni-routing process also uses the available routing space on the lower PD wiring layers 102 and 104 that is available for the multi-direction omni routing, to define omni routes that can traverse multiple equally available directions, the omni-routing process of some embodiments also uses such biasing or constraints to ensure that the route generation does not produce any or many routes that are longer than a threshold length on the available space on the lower PD wiring layers 102 and 104. In this manner, the omni routing process defines most or all of the longer wires on the higher wiring layers that are manufactured by the less advanced, second lithographic process (e.g., 193i) that produces the wider, less resistant wires.

As mentioned above, the omni routing process of some embodiments allows a route for a net to change directions along several equally available directions (e.g., two, four, eight, twelve, twenty-two, or other number of equally allowable directions that are not penalized compared to each other) as the route traverses an NPD wiring layer. When a route traverses along a PD wiring layer, the route often has to use a via to transition to another wiring layer (e.g., another PD wiring layer) to change its directions because PD routing is often biased heavily against using non-preferred directions on the PD layer. However, given that an NPD wiring layer has several equally available directions, many routes on the NPD wiring layer can change directions freely among the available routing directions without needing to use a via to traverse to another layer.

The NPD wiring layers of some embodiments has fine-grid wiring that allows these NPD layers (1) to serve as robust wiring resources to connect to lower device layer(s) and in some cases lower wiring layers, and (2) to serve as intermediate wiring layers between the fine-grid lower device/wiring layer(s) and coarser-grid upper PD wiring layers. For instance, in some embodiments, the circuit components (e.g., cells) are defined on a fine-pitched, Manhattan grid on the device layer and in some cases one or two wiring layers above the device layers. These circuit components in some embodiments have pins designed for contact on a specific Manhattan grid because the IC’s physical design uses circuit blocks (e.g., cells and IP blocks) that use the vertical and horizontal wiring that is commonly used today.

In some of these embodiments, PD Manhattan wiring is also used for conductive interconnects/wiring (e.g., the polysilicon conductors, wires, etc.) that form the devices (e.g., the transistors) and circuit components (e.g., cells, logic gates, flip flops, etc.) on the device layer(s) and in some cases one or two wiring layers above the device layer(s). The IC device and metal stack of some embodiments has a first set of one or more finer-grid NPD wiring layers above the device layer(s) and then uses a second set of one or more coarser-grid PD wiring layers above the first set of NPD wiring layers.

Between the device layer(s) and the first set of one or more NPD wiring layers, the IC stack of some embodiments also has a third set of one or more PD wiring layers (e.g., the PD, Manhattan wiring layers 1 and 2 above the device layer(s)). This third set of wiring layers are used to connect the circuit components (e.g., devices) defined on the device layer in order to form larger components (such as cells, IP blocks, etc.). The wiring on the NPD wiring layers in some embodiments is commonly employed in areas with high pin density, such as standard cell areas and areas connecting around macro cells. Also, some embodiments use a more advanced, lithographic process (e.g., EUV) to produce the devices and interconnects on the finer-grid device layer and the finer-grid first and third sets of wiring layers mentioned above, while using a less advanced, lithographic process (e.g., 193i) to produce the interconnects on the second set of wiring layers mentioned above.

Accordingly, given the finer-grid wiring resources that can be used in a large number of equally available wiring directions on the finer-grid NPD wiring layers, these NPD wiring layers in some embodiments (1) serve as a superior set of wiring layers for connecting to the finer-grid devices and components of the device layer(s), and (2) serve as superior set of intermediate wiring layers between the fine-grid lower device/wiring layer(s) and coarser-grid upper PD wiring layers. Because of their finer grid, these NPD wiring layers provide wiring locations and directions that allow for higher connection density to their lower layers. In turn, this higher connection density of the NPD wiring layers to the lower layers reduces the total number additional higher PD wiring layers that are needed to complete the IC design, as well as cost of the composition of these additional layers.

After a few NPD wiring layers that are manufactured using the more advanced lithographic process, a significant number of routes for a significant number of nets in some embodiments have been completed by just using the NPD wiring layers and wiring layers below the NPD wiring layers. At this stage, the number of remaining nets that do not have their routes completed in some embodiments has dropped sufficiently so that the routes for these remaining nets can be completed by using the higher wiring layers that are manufactured with the less advanced second lithographic process.

As mentioned above, these higher wiring layers are PD wiring layers, as each of these layers has more than a particular threshold of route segments on that layer (with the threshold being common to all these PD layers or different for different PD layers) traverse along the preferred direction of that layer. In some embodiments, the preferred directions of the PD layers can be horizontal, vertical and/or diagonal, with the preferred direction of adjacent PD layers changing. In some embodiments, these higher PD wiring layers are used for longer wires (e.g., wires that provide more global connections). For such wires, it is advantageous to use the higher wiring layers as the wires will be coarser and have less resistance than the finer-pitched wires on the lower NPD wiring layers.

The flexibility to change directions between several available routing directions on an NPD layer not only reduces the need to use vias between multiple layers to change directions, but also can increase the route/wire density on each NPD wiring layer, can reduce the number of routes that have to traverse to a higher layer in order to be completed, and can reduce the density of pin contacts that need to be defined on the higher wiring layers to ensure sufficient route connections to the pins.

All of these advantages (e.g., reduction in number of vias needed to change directions, increase in route density on the NPD wiring layers, reduction of the pin density from the lower layers to the higher layer, etc.) allow the IC’s metal stack (1) to be shorter and/or (2) to transition earlier from a more advanced lithographic technology to a less advanced lithographic technology in order to manufacture wider-pitch and lower-cost wiring layers earlier in the metal stack. In this manner, the use of a few NPD wiring layers along with the multi-direction omni routing process of some embodiments enables use of fewer wiring layers that use the most advanced lithographic process, which in turn makes the transition to less advanced lithographic process(es) (e.g., 193i) sooner in the metal wiring stack, thereby reducing the IC cost and improving yield.

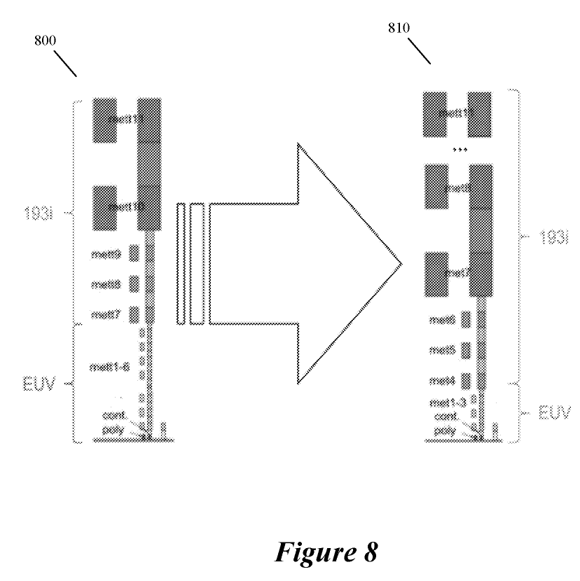

FIG. 8 pictorially illustrates these advantages by contrasting the wiring stacks of two ICs that are both manufactured by using EUV and 193i lithographic processes, with the physical design of one IC using NPD wiring layers and the physical design of the other IC not using NPD wiring layers. An IC stack includes the device layer stack and the wring layer stack.

The illustration in FIG. 8 shows that the use of the multi-direction omni routing on the NPD wiring layers allows the IC stack to be shorter and transition earlier to the less advanced 193 process. Specifically, this figure contrasts the IC stack 800 of a first IC that is manufactured with only PD Manhattan wiring with the IC stack 810 of a second IC that is manufactured with several NPD wiring layers as well as several PD wiring layers. This figure shows that the EUV lithography process is used for the device layer(s) and the first six PD, Manhattan wiring layers of the first IC, followed by the 193i lithography process being used for the next five PD, Manhattan metal layers.

This figure shows that the EUV lithography process is used for the device layer(s) and the first three metal layers in the IC stack 810 of the second IC, followed by the 193i lithography process being used for the next eight metal layers. In the IC stack 810, the third and fourth metal layers are NPD wiring layers that have wire connections defined through multi-direction omni routing. This routing is also used to define multi-direction omni routes on any available routing space on the first two PD wiring layers. The use of multi-direction omni routing allows for the EUV lithography to be just used to manufacture the device layer(s) and these first three metal layers, and then the less expensive, less advanced 193i lithographic process to be used to manufacture the metal layers four through eleven.

The use of multi-direction omni routing on a few NPD wiring layers allows the metal stack 810 to transition earlier to the less expensive 193i lithography process than the IC stack 800. As shown, the stack 810 transitions to 193i after metal layer 3, while the stack 800 transitions to 193i after metal layer 6. The earlier transition to the less expensive 193i lithography process in the IC stack 810 allows this stack to have thicker wires earlier in the metal stack for earlier use of lower resistant, thicker wires that are more optimal for longer connections.

This earlier transition reduces the overall number of layers that will need the more expensive EUV advanced lithographic process from six to three, as shown, and allows the less advanced 193i lithographic process to be used earlier in the stack to produce wider pitch wires (with lower resistance that is more ideal for longer wire connections) earlier in the stack. In some embodiments, the use of NPD routing on fine-pitched lower NPD wiring layers can also reduce the overall number of wiring layers.

As a general rule, the layers at the top of the wiring stack in some embodiments are thicker, wider, and on less dense pitch than those at the bottom. The upper routing layers are sized based on their ability to carry current and provide connections to the outside world. Bottom layer pitches are thinner, narrower, on a dense pitch and higher resistance. Pitch of these bottom layers is defined as needed to connect the cell pins. Routing pitch of a particular layer defines how it is to be lithographically printed and processed.

Some embodiments use different lithographic processes to manufacture different IC layers with different pitches. For instance, some embodiments (1) use 193 nm lithography to print wiring layers with pitches of 64 nm or higher, (2) use 193i double patterning to print wiring on wiring layers with pitches of 36 nm to 64 nm, and (3) use EUV to print layers with pitches below 36nm. With shrinking pitches, the wires become narrower, which increases resistance per micron.

The different lithographic processes have differing costs but generally the cost of lithography increases as the pitch gets smaller. This provides incentive to keep the number of layers requiring the most expensive lithographic processes to a minimum. Hence, some embodiments optimize the use of the different lithographic processes to manufacture the different layers in the IC stack in order to minimize cost, maximize yield, and improve performance. By optimally using NPD and PD routing for NPD wiring layers and PD wiring layers, the routing process of some embodiments achieves this optimization, as it makes the best use of fine pitch metal layers for the multi-direction wiring on the NPD wiring layer, while allowing wider pitches that can use cheaper lithography methods to be used earlier in the metal stack.

Some embodiments use some of the newer power delivery networks to increase the space available for omni direction routing on one or more of the lower wiring layers. In general, power routing styles come in three basic types, though others are possible. A first and most restrictive style is using metal 2 and metal 1 for power delivery. This approach can greatly restrict the ability to cross from row to row (e.g., between standard cell rows) on metal 2 and metal 1, and leaves metal 3 as the primary NPD wiring layer for routing. The metal 3 multi-direction routing can move in any direction either from row to row or down the row.

Some embodiments use a second power delivery style, which simply uses metal 1 along the direction of the row. In this situation both metal 2 and metal 3 can be freely used for multi-direction routing. Other embodiments use a third power delivery style, which employs the newer buried power rails topologies. These topologies use a power rail embedded in the wafer under the transistor devices. In this situation there is no metal 1 blockage for routes from row to row. In this case metal 1 can be used for multi-direction routing, subject to blockages within the cell, as well as metal 2 and metal 3. While the exemplary embodiments mentioned above refer to metal 1, metal 2, and metal 3 for multi-direction routing, it is possible to also use layers above metal 3 and in some cases metal 0 (also referred to as local interconnect) for the multi direction routing and wiring. Use of these layers depends on the routing goals, complexity of the SoC, and/or size of the SoC.

To increase the space available for omni direction routing on one or more of the lower wiring layers, some embodiments use a backside power delivery (BSPD) network for the ICs that they design and manufacture. In some embodiments, this BSPD also uses buried power rails.

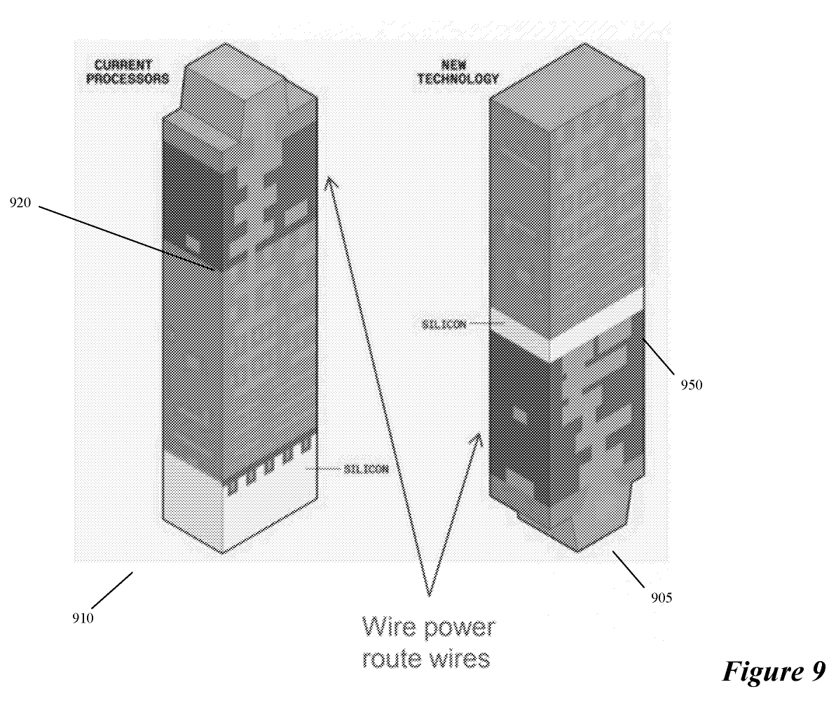

FIG. 9 illustrates an example of a BSPD network 905 for an IC as well an example of a more traditional front side power delivery (FSPD) network 910. Power delivery networks, PDN, are often specified before the physical design routing is performed. A PDN specifies the interconnect and I/O (input/output) network for delivering power starting outside of the chip, through the I/O cells, through various IC layers all the way to the device and cell layer.

The PDN can include interconnects (e.g., power delivery mesh) that serve as blockages to the multi-direction omni routing of some embodiments. This is the case for the FSPD network 900 of FIG. 9. In the FSPD network 900, the power is delivered from the top-metal layer 920 all the way down to the lowest metal layer, and then from this metal layer to the device layer (e.g., the transistor layer). Since this power delivery network traverses from the topmost to the bottommost metal layers, it consumes all lot of space, which would otherwise have been available routing resources for the physical design routing. This consumption of routing resources is especially undesirable on the lowest metal wiring layers as these layers have very little space that is not consumed by the wiring that is used to define the devices, logic gates, standard cells and other basic circuit components.

Hence, some embodiments use a BPSD network to deliver power to the IC in a manner that does not consume any of the higher metal layers and either none of the lower metal layers or a minimal amount of the lower metal layers. The BPSD network (such as network 905) in some embodiments uses buried power rails. For instance, the BPSD network of some embodiments uses a power rail embedded in the wafer under the transistor layer(s). Under this approach, the power delivery network causes no blockages on the lowest metal layers. Hence, the available space (i.e., the space that is not consumed by the wiring that is used to define the devices, logic gates, standard cells and other basic circuit components) to be used by the omni router.

As shown, in the BSPD network 905, the power is delivered power from the back side 950 of the die to the device layer on which the transistors are defined. This style is more complex and expensive. However, BPSD is more advantageous for signal routing as BSPD consumes no routing resources on metal layers 2 and higher, while consuming little routing resources on metal layer 0, and even less routing resources on metal layer 1. Moreover, the routing is not forced to contend with large power structures on metal layers 1 and higher in order to cross an arrangement of circuit components (e.g., to cross from one cell row to another cell row). These advantages are especially beneficial for the omni routing of some embodiments as this style of routing explores multiple equally available routing directions on each NPD routing layer, which more freely takes advantage of the additional available routing resources.

As mentioned above, the multi-direction omni routing of some embodiments uses a strategy of shorter connections on NPD wiring layers and also reduces pin density vertically in the metal stack and produces shorter connections. The multi-direction omni routing of some embodiments uses the strategy of routing shorter connections by first trying to keep the routes for these connections on the lower NPD layers. This strategy allows many of the connections to be implemented in the lower layers leaving more room to switch to wider pitches on higher layers for longer routes.

In general, shorter connections have a much greater chance of being able to be completed on the lower NPD wiring layers. This is fortuitous because in many designs, many of the connections are shorter connections. Once the shorter connections are routed on the lower layers, the higher layers area are available for routing longer connections as mentioned above. Thus, by routing many of the shorter connections on the lower NPD wiring layers, pin propagation can be greatly reduced or even eliminated to the upper layers, which in turn greatly reduces or eliminates pin propagation density on the upper layers and thus frees up the upper metal layers more for the longer connections.

By not limiting the routing directions to just the horizontal direction or just the vertical direction on an NPD layer, the omni-router of some embodiments can produce shorter length connections on that layer as a direct connection between two nodes on that layer can be a straight line or a closer approximation to the straight line connection than the L-shape connection that would typically be produced through wiring on two layers when Manhattan routing is used. Connections along PD wiring layers that are primarily vertical or horizontal are routed with distances comparable to orthogonal routing. Also, the resulting shorter connections on the NPD wiring layers for the respective node pairs typically have fewer edges making them easier to manufacture.

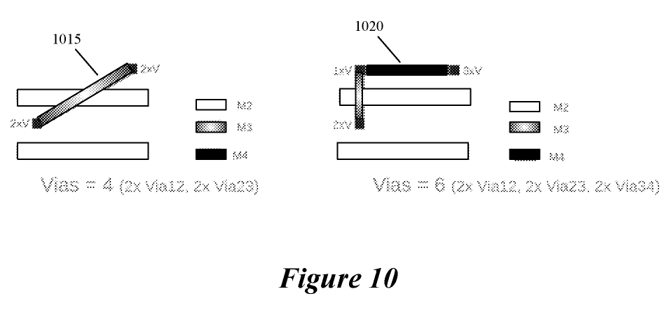

FIG. 10 illustrates an example of a straight-line diagonal connection 1015 formed on an NPD metal layer 3 between two nodes and contrasts this shorter length with the longer L-shaped connection 1020 formed by a vertical connection on preferred vertical direction M3 and preferred horizontal direction M3. The cost for the shorter connection 1015 is only 4 vias, a pair of vias to go up and then down between metals 1 and 2, and a pair of vias to go up and then down between metals 2 and 3. The via cost of the longer connection 1020 is 6 vias, a pair of vias to go up, then down between metals 1 and 2, and a pair of vias to go up and then down between metals 2 and 3, and a pair of vias to go up and then down metals 3 and 4.

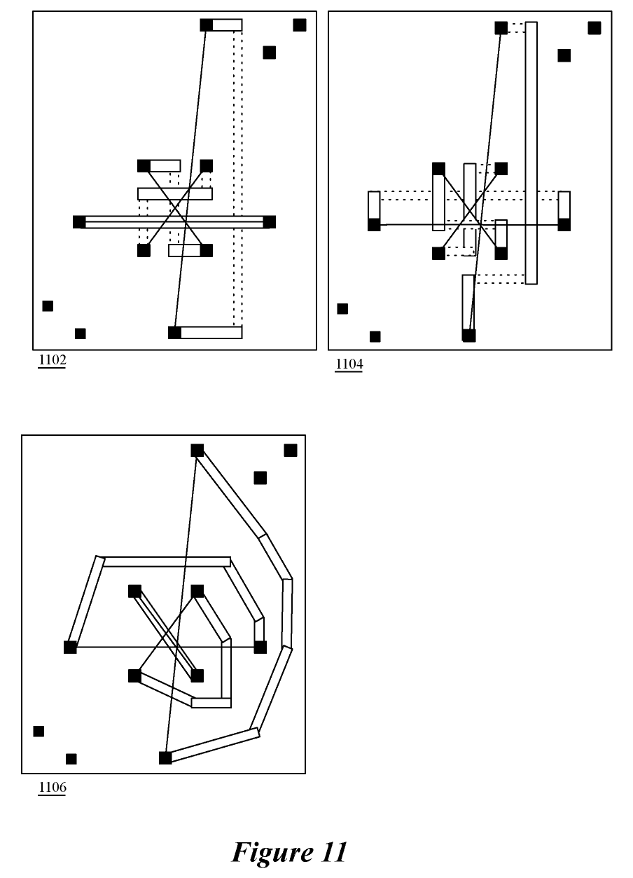

FIG. 11 presents another example that illustrates the benefit of using omni-directional routing on one NPD wiring layer. This example involves four pairs of nodes (e.g., pins, contacts) for four nets that need to be connected (the nodes represented by solid black squares and the unrouted connections by thin black lines). This example contrasts two different routing solutions 1102-1104 for connecting these four pairs of nodes through just Manhattan wiring on three Manhattan wiring layers against one routing solution 1106 that connects each pair of these nodes through one multi-direction route on one NPD wiring layer. As shown, while the two routing solutions 1102 and 1104 use many vias to define their respective routes, the multi-direction routes in the routing solution 1106 use no vias to define each of these routes, because vias are not needed to connect the different segments of each of these routes when these segments change directions.

For the highest completion ratio using the omni multi-direction router, the router of some embodiments also allows longer multi-direction routes on an NPD wiring layer. This approach provides the most reduction in pin density from the lower to upper layer. However, this approach can produce a route for a node pair that is longer than the route that would have been produced for this node pair had just Manhattan wiring on PD Manhattan layers been used. The longer looping omni-routes can also create obstacles for other routes and suffer from greater resistance degradation due to the typically finer pitch on the lower NPD wiring layers. To alleviate some of these disadvantages, some embodiments limit the use of long omni-direction routes on an NPD wiring layer to wide-and-short regions or narrow-and-tall regions (e.g., regions between standard cells).

In some embodiments, the wiring connections on lower NPD wiring layers (such as third and fourth layers, or first to fourth layers) are defined with an NPD first router, while the wiring connections on the upper PD wiring layers (such as layer five and higher) are defined by a PD second router (e.g., a Manhattan router). The NPD first router produces routes on each of the lower layers that traverse more than eight different directions on each of these layers, and in some embodiments also produces curvilinear routes on the lower wiring layers. The use of such routers is further described below. In other embodiments, however, the routing on the lower NPD wiring layers and the routing on the upper PD wiring layers is all performed by a single router that can perform both PD and NPD (e.g., Manhattan and/or diagonal) routing.

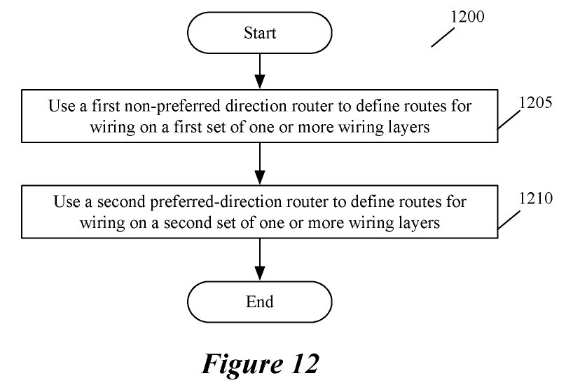

FIG. 12 illustrates a routing process 1200 of some embodiments that defines routes to connect a net list associated with a design of an IC. A netlist identifies several nets, with each net corresponding to two or more nodes in the IC design that need to be connected by one or more routes. As shown, the process 1200 uses (at 1205) a first non-preferred direction router to define routes on a first set of wiring layers (e.g., a lower set of wiring layers), and uses (at 1210) a second preferred-direction router to define routes on a second set of wiring layers (e.g., a higher set of wiring layers located above the first set of wiring layers). In some embodiments, the second router (used at 1210) is one of the commercially available preferred-direction routers sold today, e.g., routers sold by Cadence, Inc. or Synopsys, Inc. The first set of wiring layers may include the first and second wiring layers, first through fourth layers, or another set of the lower wiring layers (e.g., the third and fourth wiring layers, as shown in FIG. 1 above, if the first and second wiring layers use PD wiring for devices and/or circuit blocks). The second set of wiring layers, in some embodiments, includes a number of wiring layers above the first set of wiring layers (e.g., fifth through seventh wiring layers, fifth through tenth wiring layers, etc.).

The routes on the NPD lower wiring layers traverse in more than eight directions (e.g., 16, 20, 32, 90, 180, 360, etc. directions). These routes on the lower wiring layers are all piecewise linear (including straight single line segment routes) in some embodiments, while in other embodiments the routes on all of the lower layers can also include curvilinear routes. The routes on the PD wiring layers may use Manhattan preferred directions and/or other PD wiring (e.g., 45 or 60 degree wiring) in different embodiments.

In some embodiments, the routes defined by the first router connect node pairs that are within a threshold distance of each other (or at least primarily node pairs that are within that threshold distance of each other), while the routes defined by the second router connect node pairs that are more than that threshold distance from each other (or at least primarily node pairs that are further than the threshold distance from each other).

To connect node pairs that are more than the threshold distance from each other, in some embodiments the routing process 1200 uses both the first and second routers, e.g., uses the first router to define the route segments that traverse along the lower non-preferred direction wiring layers and uses the second router to define the route segments that traverse along the upper preferred direction wiring layers. To facilitate the operation of the second router in cases where the second router has to complete a route that is partially completed by the first router, the first router in some embodiments defines one or more of its route segments on the first set of NPD wiring layers up to locations used on these layers to via to the second set of wiring layers. The second router then commences its routing operations from these via locations in order to complete the routes that were only partially completed by the first router.

Some embodiments first define the routes that traverse the lower first set of wiring layers of the IC design and then define the routes that traverse the higher wiring layers of the IC design. For instance, some embodiments perform global routing and then perform a first NPD detailed routing followed by a second PD detailed routing. Global routing defines, for each net, a global route that more generally defines the route for the net (e.g., defines a general area in the design layout traversed by the route). Detailed routing defines the actual route for each net. Other embodiments perform NPD detailed routing for the lower first set of wiring layers of the IC design without first performing global routing for these layers. Some such embodiments then perform PD global routing and then PD detailed routing to define routes that use the higher second set of PD wiring layers of the IC design.

The NPD detailed routing does not restrict its path search processes to search only one or more preferred wiring directions or penalize the other wiring directions on the first set of wiring layers. Instead, the NPD detailed routing allows its path search to explore any angle for its route expansion, and then subsequently geometrizes the routes through the use of curvilinear wire segments to produce curvilinear routes. In other embodiments, the NPD detailed routing only explores path searches in a large, finite number of wiring directions, such as nine or more wiring directions, and does not produce designs with curvilinear route segments.

The first set of wiring layers (NPD layers) may include multiple subsets of wiring layers in some embodiments. In some such embodiments, the NPD router performs detailed routing for a first subset of the NPD wiring layers (e.g., for the third wiring layer) and then performs detailed routing for a second subset of the NPD wiring layers (e.g., for the fourth wiring layers). For instance, the NPD router can recursively call the NPD router to perform the detailed routing on the second subset of NPD wiring layers (and so on if detailed routing needs to be performed for additional subsets of NPD wiring layers).

As noted above, in some embodiments a single router defines the routes on both the first and second sets of wiring layers. In some such embodiments, the router behaves differently (e.g., uses different sets of design rules) when defining routes on the first set of wiring layers as compared to routes on the second set of wiring layers. That is, the single router uses a first set of design rules to perform NPD routing on the first set of wiring layers and a second set of design rules to perform PD routing on the second set of wiring layers (as well as, in some cases, for one or more regions of the first set of wiring layers in which components such as transistors and/or circuit blocks are located). Alternatively, in some embodiments the router uses a third set of design rules to perform PD routing on one or more regions of the first set of wiring layers.

In either case, the first set of design rules includes design rules for performing NPD routing on NPD wiring layers and/or NPD wiring regions (e.g., design rules to define piecewise linear and/or curvilinear routes, design rules to use a particular set of NPD routing models (also referred to as interconnect models), design rules to only define routes smaller than a threshold length, etc.). The second set of design rules includes design rules for performing PD routing on PD wiring layers and/or regions (e.g., design rules to define piecewise linear routes, design rules to define routes using a particular routing model (e.g., Manhattan routing, 45-degree diagonal routing, 60-degree diagonal routing, etc.)).

As mentioned above, a route for a net is a collection of one or more route segments (and, in some cases, one or more vias) in an IC design that represents the eventual wire segments (and, in some cases vias) of the IC that electrically connects the pins of the net. To route a set of nets for an IC design (on the lower NPD layers or the upper PD layers), some embodiments define one or more connections per net. To do so, a set of one or more connections is defined for each net (which includes two or more pins). For example, one connection is defined for a two-pin net, two connections are defined for a three-pin net, three connections are defined for a four-pin net, etc.

Each connection has two nodes: (1) two pins, (2) two subnets, or (3) a pin and a subnet. A subnet is an earlier defined set of one or more route segments for the same net. For example, in a three-pin net, a first connection is defined between two of the pins, and a second connection is defined between the third pin and a location along the first connection (i.e., a subnet). The location of a subnet can be defined along any point of another connection, including at the middle of the other connection or on one of the pins of the other connection. Each three-pin or more net has at least one subnet that acts as a node during routing (e.g., a four-pin net can have two subnets between which a connection is defined).

Some embodiments define routes on a per-connection basis rather than a per-net basis. In some embodiments, one net is routed on one or more layers, with different connections routed on different sets of one or more layers. For instance, a first connection of a net could be routed on metal layer 1 and a second connection routed on metal layer 4, with the two connections connected using multi-layer interfaces (e.g., vias). A net with both short and long connections can have the short connections routed on the NPD layers (and, in some cases, on one or more PD layers) while the long connections are routed on the upper PD layers. In other embodiments, routes are defined on a per-net basis. In this case, shorter nets are routed on the lower NPD layers (e.g., due to high resistance of long thin routes made on the NPD layers) while long nets are routed on upper PD layers. Conjunctively or alternatively, in some embodiments, one net routed all at once can have its route traverse multiple metal layers, with its wire segments on different metal layers connecting at multi-layer interfaces (e.g., vias). Routing shorter connections of a long net on the lower NPD layers helps increase the connection density on these lower NPD metal layers.

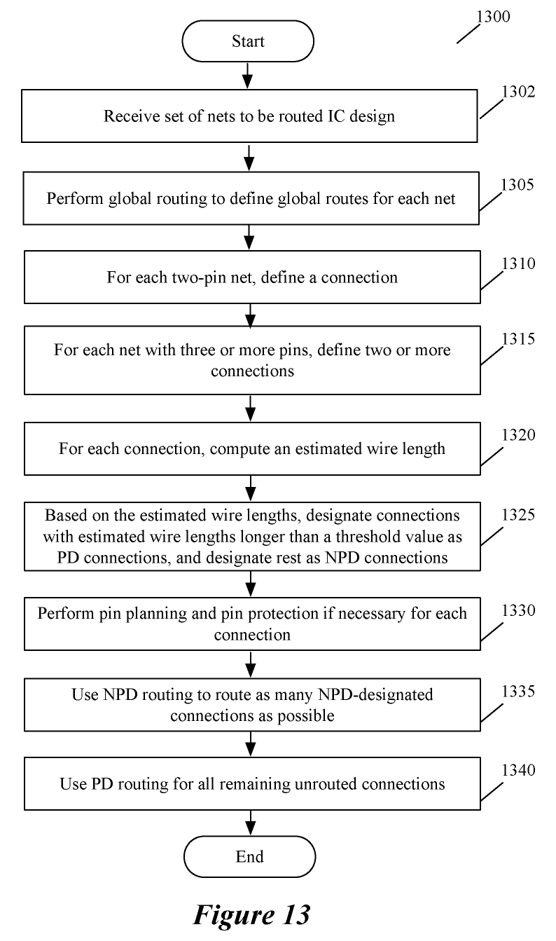

FIG. 13 conceptually illustrates an overall routing process 1300 of some embodiments for defining routes for an IC design. This process 1300 is in some embodiments performed by a set of routers that includes both a first NPD router and a second PD router, and will be described below as using the set of routers. It should be understood, however, that in other embodiments the process 1300 is performed by a single router that defines routes on both NPD-designated layers and PD-designated metal layers.

The process 1300 begins by receiving (at 1302) a set of nets to be routed for an IC design. The process then performs (at 1305) global routing to define global routes for each net. The global routing defines, for each net, a global route that more generally defines the route for the net (e.g., defines a general area in the design layout traversed by the route). For instance, in some embodiments, one of the NPD or PD routers divides an IC design layout into individual global routing areas, called Gcells. Then, a global route (Groute) is created for each net by listing the global routing areas (the Gcells) that the Groute for the net should pass through.

In some embodiments, the global routes can partially traverse all available wiring layers of the IC design (e.g., M1 and up, M0 and up). In some embodiments, global routes are defined without reference to particular wiring layers crossed by the global routes. In some embodiments, all of the global routes are defined as PD global routes, including routes that will be routed using an NPD detailed router. In other embodiments, at least a subset of routes is defined as NPD global routes. The global routing can be performed by the NPD router, the PD router, or both (e.g., each router defines a subset of global routes). In other embodiments, the global routing is performed by a global router that is separate from either the NPD or PD detailed routers.

Next, for each two-pin net, the process 1300 defines (at 1310) a connection. In some embodiments, the NPD router defines one connection (i.e., a pin/pin connection) for each two-pin net that is to be routed in the IC design.

For nets with three or more pins (a several-pin net), the process 1300 defines (at 1315) two or more connections. Each of these connections for a several-pin net can include two pins, a pin and a subnet, or two subnets. Defining multiple connections for a several-pin net enables the routing of different connections for the same net at different times (e.g., with some connections being routed by the NPD router and others later by the PD router). In some embodiments, for a given several-pin net, the process first defines one or more two-pin connections (e.g., using pairs of pins that are closest to each other) to form subnets. The process then defines connections to connect these subnets either to each other or to remaining pins. This process continues until enough connections are defined to route the entire net.

In some embodiments, for a several-pin net, the process first identifies the closest two pins and defines a connection between these two pins. The closest pins may be determined based on straight-line distance between each pair of pins in the net, bounding boxes for each pair of pins in the net, etc. This connection is now treated as a subnet for subsequent connection definition. In some embodiments, the next closest pair of remaining pins is identified, and a connection is defined for these pins, and so on until either all of the pins are paired into connections (for nets with even numbers of pins) or all but one of the pins are paired into connections (for nets with odd numbers of pins). The remaining pin (for nets with odd numbers of pins) is then paired with the closest subnet (e.g., measured by a bounding box that contains the entire subnet and the pin, or by straight-line distance from the pin to a closest location on the subnet). For nets with at least four pins, the subnets are then connected in pairs (i.e., defining connections between pairs of subnets that are closest together) until the entire net is connected. It should be understood that other embodiments may use different heuristics to select pins and/or subnets to connect and/or a different algorithm for selecting which nodes (subnets and/or pins) to connect in which order (e.g., connecting two close subnets prior to connecting either to a further-distanced pin).

The process 1300 then computes (at 1320) an estimated wire length for each of the defined connections. Some embodiments compute estimated wire lengths of the connections in order to identify “short” connections (i.e., connections with an estimated length shorter than a particular threshold distance value). In different embodiments, the NPD router uses different heuristics to estimate the wire length of each connection. For instance, the estimated wire length may be computed by computing a node-to-node distance (each node being a pin or a subnet) using vectors or by using bounding boxes that bounds the nodes of the connection.

Based on the estimated wire lengths, the process 1300 designates (at 1325) connections with estimated wire lengths longer than a threshold value as PD connections and designates the rest of the connections (i.e., connections shorter than the threshold value) as NPD connections. As described above, the routes on the lower NPD layers are manufactured using a more advanced lithographic technology that fabricates thinner wires. These thinner wires have a higher resistance and hence suffer signal degradation when traversing longer distances, so longer routes are designated for the PD layers that use thicker wires.

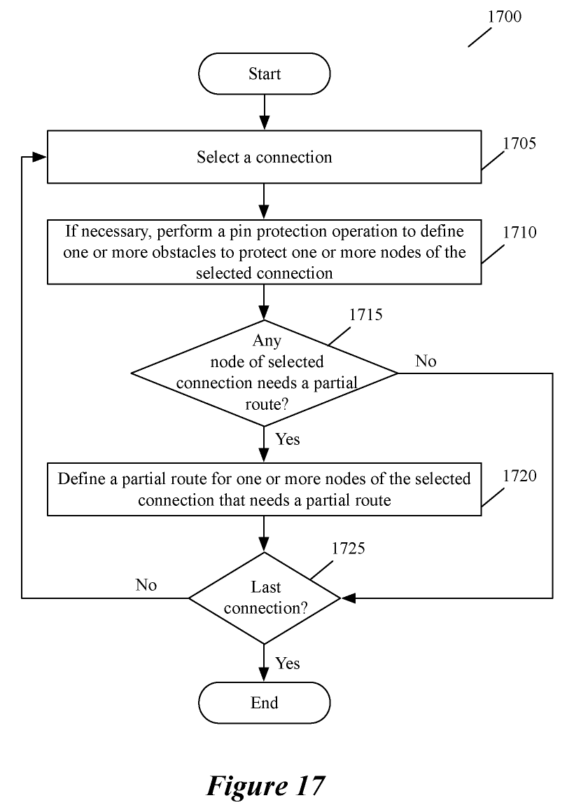

The process 1300 then performs (at 1330) pin planning and protection, if necessary, for each connection. In some embodiments, pin planning entails (i) determining the type of connection to use between two pins (e.g., NPD or PD) and (ii) how to protect each pin during routing of other connections. In some embodiments, pin planning can also entail defining partial routes and adding virtual pins for a connection. Some embodiments examine each connection (i.e., each PD-designated connection and each NPD connection) to determine whether pin planning and/or protection is needed for the connection, while other embodiments perform pin planning and protection only for PD-designated connections. Further information regarding pin planning and pin protection will be described below in relation to FIG. 17.

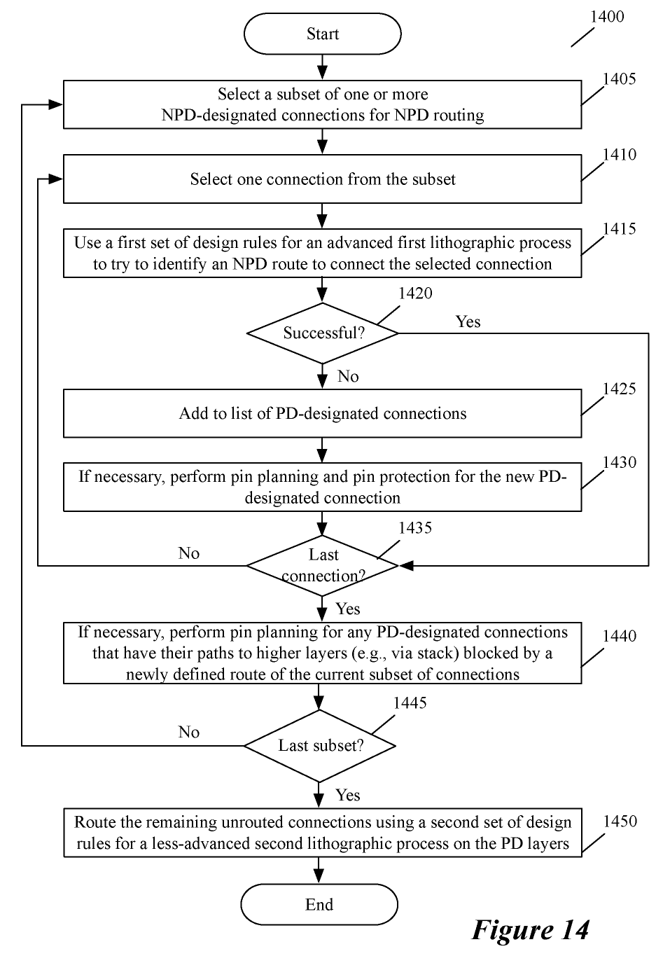

At 1335, the process 1300 uses NPD routing to route as many NPD-designated connections as possible. The NPD router uses a first set of design rules to try to define as many routes for as many NPD-designated connections as possible. The first design rule set in some embodiments includes design rules for performing NPD routing, such as curvilinear and/or piecewise linear multi-angle (e.g., 11.25 angle, all angle, etc.) routes. The first design rule set in some embodiments is defined for a first lithographic technology (e.g., EUV lithography) and specifies a feature size associated with the first lithographic technology. In some cases, an NPD-designated connection is unable to be routed on the NPD layers (e.g., because a short enough route cannot be found or because no route can be found). In this case, the NPD router redesignates the connection as a PD connection to be routed by the PD router. Further information regarding NPD routing of NPD-designated connections will be described below in relation to FIG. 14.

Lastly, the process 1300 uses (at 1340) PD routing for all remaining unrouted connections. Once the NPD router has finished routing the NPD connections (and/or designating any NPD connections for PD routing instead), the PD router uses a second set of design rules to define routes for all remaining connections. These connections include PD connections initially designated for PD routing (e.g., based on their length), and connections initially designated for NPD routing but that were unable to be routed on the NPD wiring layers. The second design rule set in some embodiments includes design rules for routes on PD wiring layers and/or regions, such as piecewise linear routes along preferred Manhattan or diagonal directions. The second design rule set in some embodiments is defined for a second lithographic technology (e.g., 193i lithography) and specifies a second feature size associated with the second lithographic technology. After all remaining unrouted connections are routed, the process 1300 ends.

As mentioned above, the NPD router uses a first set of design rules to define routes on NPD wiring layers and/or regions, and the PD router uses a second set of design rules to define routes on PD wiring layers and/or regions. In some embodiments, (1) the NPD router uses the first design rule set to define routes on NPD layers and/or regions, (2) the PD router uses a second design rule set to define routes on the PD layers and/or regions, and (3) the NPD router uses a third design rule set to perform PD routing on the lower NPD layers. This third design rule set is in some embodiments defined for the same first lithographic technology (e.g., EUV lithography) as the first design rule set but is used to perform PD routing. In some of these embodiments, the NPD router does not perform PD routing on the upper PD layers, and only uses the third design rule set to perform PD routing in PD regions of the lower NPD layers (e.g., regions for circuit blocks, such as IP blocks).

In other embodiments, the NPD router does not use the third set of design rules on the lower NPD layers to perform PD routing, as it only performs NPD routing. In some of these embodiments, the lower NPD layers have no regions for PD routes. Alternatively, in some embodiments, the PD router defines PD routes on portions of the lower NPD layers (e.g., for circuit blocks) using the third set of design rules.

After global routing is performed at 1310, some embodiments also define one or more routing boxes, with each routing box including one or more Gcells defined during global routing. After global routing is performed, the NPD router (or PD router, in some cases) deconflicts routes and define edges of the routing boxes. Then, when routes are being defined, they are defined one routing box at a time. If a net spans multiple routing boxes, a partial route of the net is routed during routing of each routing box it spans, and these partial routes are stitched together after routing all routes in all routing boxes.

In embodiments where one router performs the entire process 1300, the one router uses all design rule sets, and uses the first design rule set for performing NPD routing and the second design rule set for performing PD routing. The router in some embodiments also uses the third design rule set for performing PD routing on one or more regions of the NPD layers (e.g., for circuit blocks). Different design rule sets are used in some embodiments so different metal layers of one IC design can be routed as PD layers or NPD layers. Conjunctively or alternatively, different design rules sets are used in some embodiments so different portions of a same metal layer can be routed with PD and NPD routing. When using one router to perform both PD and NPD routing, the router is also able to know which design rule set to use for each route it is defining (based on which metal layer on which the route is being defined and based on the portion of the metal layer on which the route is being defined).

As mentioned above, a router (e.g., an NPD router) in some embodiments tries to define routes on NPD layers for as many NPD-designated connections as possible. When an NPD-designated connection cannot be defined using an NPD route, the connection is redesignated and added to the list of PD-designated connections so that the PD router can define a route for the connection.

FIG. 14 conceptually illustrates a process 1400 of some embodiments for defining routes (i.e., detailed routes) for connections of an IC design. This process 1400 is performed in some embodiments by a router (e.g., an NPD router, or one router that performs both NPD and PD routing) after connections have been defined and classified for nets of the IC design, and after any necessary pin planning and protection is performed. For example, some embodiments perform the process 1400 at operations 1335 and 1340 of the process 1300 described above.

The process 1400 begins by selecting (at 1405) a subset of one or more NPD-designated connections for NPD routing and selecting (at 1410) one connection from the selected subset. In some embodiments, the router performs routing for groups of connections (subsets) at a time, then evaluates the routing of such a group of connections. As is common in routing, a router does not typically just select one connection (or net) at a time, route that connection, and move on. A router may perform routing for a subset of connections, evaluate the routes, and determine whether to keep these routes or rip up the routes and re-try routing for either the same subset or a different (potentially partially overlapping) subset of connections. In some embodiments, the subsets are a predefined number of connections (e.g., ordered from shortest to longest connection, as measured by bounding box or another estimate of route length). Within a subset, some embodiments select the shortest remaining connection (i.e., route the connections in order from shortest to longest).

For the selected connection, the process 1400 uses (at 1415) a first set of design rules for an advanced first lithographic process to try to define a route to connect the selected connection. The first design rule set includes design rules for defining routes on NPD layers associated with the advanced first lithographic process. For example, the first design rule set in some embodiments includes design rules specifying a particular set of routing models to use to define a route for the connection, a particular threshold distance value under which the route for the connection should be defined, etc. Using these design rules, the router tries to define a route on one or more of the lower NPD layers of the IC design.

The process 1400 then determines (at 1420) whether defining a route for the selected connection was successful (i.e., whether the router was able to define a route for the connection). A route may not be able to be defined for a connection because of obstacles (e.g., other pins, other already routed connections) blocking all potential routes for the connection, because the shortest available route for the connection violates a length constraint defined in the first design rule set, or any suitable reason as to why a connection cannot be defined. If a route was successfully defined for the selected connection, the process 1400 proceeds to step 1435, described below.

However, if the NPD router was unable to successfully define a route for the connection, the process 1400 adds (at 1425) the selected connection to a list of PD router designated connections. Because no route could be defined for the connection by the NPD router, the router redesignates the connection for PD routing, to be routed using the upper PD layers of the IC design.

If necessary, the process 1400 then performs (at 1430) pin planning and pin protection for the new PD-designated connection. Because the selected connection is now designated for PD routing, some embodiments delay the routing of that connection until all of the NPD-designated connections for the IC design have been routed (or at least until the router has attempted to route all of the connections designated for NPD routing). Because of this, dynamic pin planning and protection is performed in some embodiments to ensure that PD routing for the selected connection can be achieved. This pin planning and protection, in some embodiments, ensures that space will be available for z-axis connections (e.g., vias) from the pin(s) of a connection up to at least a subset of the upper PD layers. Further information regarding how pin planning and protection is performed will be described in relation to FIG. 17.

The process 1400 then determines (at 1435) whether the selected connection is the last connection in the selected subset of NPD-designated connections. If there is at least one connection in the subset that has yet to be selected, the process 1400 returns to 1410 to select another connection from the subset.

Once all connections from the selected subset have been selected, the process 1400, if necessary, performs (at 1440) pin planning for any PD-designated connections that have their paths to higher metal layers (e.g., using vias and/or via stacks) blocked by a newly defined route of the current subset of connections. Because PD-designated connections are to be routed on upper metal layers, one or more multi-layer interfaces (e.g., vias) are needed to connect the pins and/or subnets of these connections up to these upper metal layers. When other routes are defined before routes for these PD-designated connections, the other routes may block their via stacks from being created. As such, the router in some embodiments performs pin planning, when necessary, for any PD-designated connection for which a vertical via stack is no longer possible. In some embodiments, this pin planning involves defining a partial route (or route guide) from a pin of a PD-designated connection to a different location on a lower layer, so that a via stack can be created from this different location. Further information regarding pin planning and partial route definition for connections will be described below.

At 1445, the process 1400 determines whether the selected subset of NPD-designated connections is the last subset. If there are any subsets of one or more NPD-designated connections that have yet to be routed, the process 1400 returns to step 1405 to select another subset of NPD-designated connections. Otherwise, the process 1400 routes (at 1450) the remaining unrouted connections (which should all be designated for PD routing) using a second set of design rules for a less-advanced second lithographic process on the PD layers of the IC design.

The second design rule set includes design rules for performing PD routing on metal layers associated with the less-advanced second lithographic process. Using these design rules, the router tries performing PD routing on the PD layers for the rest of the connections (including all initially designated PD connections and any NPD connections that were not able to be routed at steps 1415) of the IC design. In some embodiments, one router that performs operations 1405-1445 also performs the operation 1450 (i.e., a single router performs PD and NPD routing). In other embodiments, an NPD router performs steps 1405-1445 and notifies a separate PD router to perform step 1450 (e.g., while passing all of the unrouted connections and existing routes to the PD router). After all connections of the IC design have been routed, the process 1400 ends.

The process 1400 above describes performing NPD routing before performing any PD routing. In other embodiments, NPD and PD routing are performed conjunctively. In some such embodiments, one router performs NPD and PD routing on all metal layers at the same time and does not perform routing per connection type (e.g., NPD vs. PD connections) or per metal layer. In yet other embodiments, routing is performed on a per-layer basis. In some such embodiments, NPD routing is successively performed for successive individual NPD metal layers, e.g., first for the first metal layer, then for the second metal layer, then for the third metal layer, and so on. Further information regarding performing NPD routing per layer is described in relation to U.S. Patent Publication 2023/0282635A1, which is incorporated herein by reference.

In some embodiments, when a router routes a connection, the router selects a routing model (also referred to as interconnect model) to use based on one or more characteristics of the connection. Such routing models are selected based on connections’ characteristics and are used to define different types of routes on different metal layers of an IC design. In some embodiments, a routing model specifies a set of one or more available routing directions. For example, in some embodiments a first routing model specifies a set of many (e.g., eight, 32, all) directions, while a second routing model specifies a set of two available routing directions (e.g., horizontal and vertical routing directions).

In some embodiments, the routing model specifies a particular primary direction or set of directions for the route. For instance, for an NPD route, that primary direction can be one of the many available routing directions for the NPD layer. When NPD routing has 16 available routing directions, some embodiments select one of these 16 available routing directions (or a subset of the 16 available directions, such as a primary direction and directions on either side of the primary direction) as the routing model for the route. For a PD route, if using Manhattan routing for the PD layers, some embodiments select either vertical or horizontal routing as the routing model for the route.

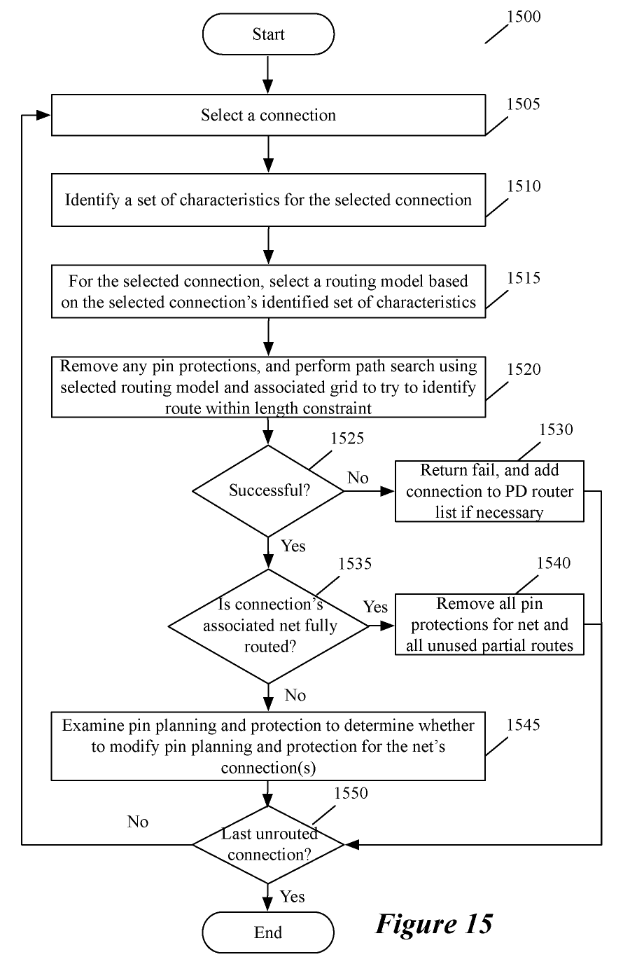

FIG. 15 conceptually illustrates a process 1500 of some embodiments for selecting different routing models for connections to use to route the connections. This process 1500 is performed in some embodiments by one router that performs both NPD and PD routing of an IC design. In other embodiments, the process 1500 is performed by an NPD router that routes NPD-designated connections of an IC design for which a separate PD router routes the PD-designated connections.

The process 1500 begins by selecting (at 1505) a connection. For the selected connection, the process 1500 identifies (at 1510) a set of characteristics for the selected connection. In some embodiments, the set of characteristics includes an estimated wire length of the connection (e.g., determined by a node-to-node distance of the connection or by a bounding box). Conjunctively or alternatively, the set of characteristics in some embodiments includes a positional relationship of the nodes of the connection. For instance, the set of characteristics in some embodiments includes an aspect ratio or other attribute of a bounding shape of the connection’s nodes.

At 1515, the process 1500 selects a routing model based on the selected connection’s identified set of characteristics. In some embodiments, the routing model selection entails (i) selecting between NPD and PD routing and then (ii) selecting a more detailed routing model for the specific selected route once either NPD or PD routing is selected. In addition, in some embodiments the selection of a routing model in this case applies specifically to NPD-designated connections (with PD-designated connections being routed later by a separate PD router).

In some embodiments, the routing model specifies a particular primary direction or set of directions for the route. For instance, for an NPD route, that primary direction can be one of the many available routing directions for the NPD layer. When NPD routing has 16 available routing directions, some embodiments select one of these 16 available routing directions (or a subset of the 16 available directions, such as a primary direction and directions on either side of the primary direction) as the routing model for the route. For a PD route, if using Manhattan routing for the PD layers, some embodiments select either vertical or horizontal routing as the routing model for the route.

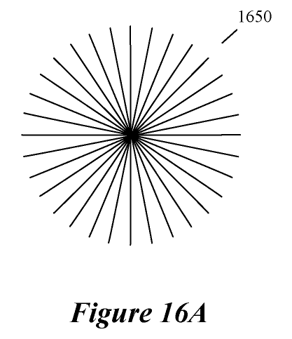

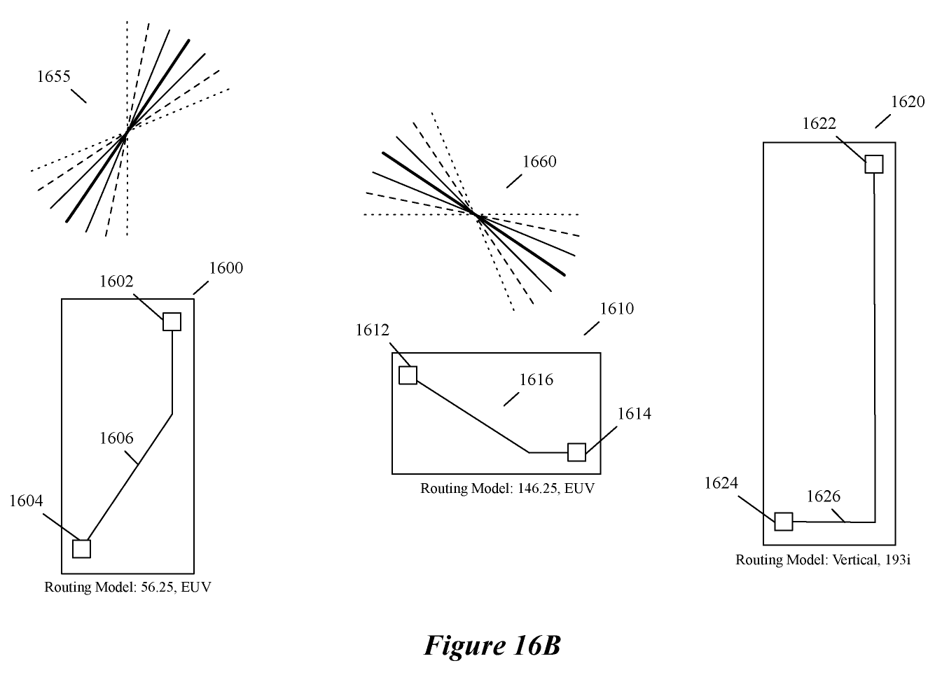

FIGS. 16A-B illustrate a set of options for routing model selection as well as the selection of specific routing models for specific connections. As shown in FIG. 16A, an NPD layer in some embodiments can have 16 different directions 1650, though it should be understood that some embodiments allow all-angle routing (i.e., any routes using any angle rather than a set of 8, 16, 32, etc. different allowable angles) and/or curvilinear routing.

FIG. 16B conceptually illustrates two examples 1600 and 1610, and 1620 of connections and optimal routing models that are selected based on the characteristics of these connections. In this figure, each connection is a pair of pins, though it should be understood that routing models are similarly selected for pin/subnet connections or subnet/subnet connections. As shown, the first example 1600 includes pins 1602-1604 and an estimated route 1606, the second example 1610 includes pins 1612-1614 and an estimated route 1616, and the third example 1620 includes pins 1622-1624 and an estimated route 1626. In some embodiments, the estimated routes 1606, 1616, and 1626 are Groutes defined during global routing.

In the first connection example 1600, the estimated route 1606 has an estimated length within a length constraint for using NPD routing, such that the connection’s route can be defined on a metal layer or set of metal layers that will be fabricated using EUV lithography. Some embodiments then select a primary direction for the route based on the positional relationship of the pins 1602-1604 and/or the estimated route 1606, as shown by the set of routing directions 1655. In this case, the selected primary direction is shown in bold, at 56.25 degrees (i.e., measured counterclockwise off of the horizontal being 0 degrees). Other secondary directions for the route are shown (in decreasing preference order) in solid line, dashed line, and dotted line.

In the second connection example 1610, the estimated route 1616 has an estimated length within the length constraint for using NPD routing, such that the connection’s route can be defined on a metal layer or set of metal layers that will be fabricated using EUV lithography. Some embodiments then select a primary direction for the route based on the positional relationship of the pins 1612-1614 and/or the estimated route 1616, as shown by the set of routing directions 1660. In this case, the selected primary direction is shown in bold, at 146.25 degrees (i.e., measured counterclockwise off of the horizontal being 0 degrees). Other secondary directions for the route are shown (in decreasing preference order) in solid line, dashed line, and dotted line.

In the third connection example 1620, the estimated route 1626 has an estimated length larger than the length constraint for using NPD routing, so PD routing should be used such that the connection’s route has to be defined on a metal layer or set of metal layers that will be fabricated using 193i lithography. The positional relationship of the pins 1622-1624 (e.g., the aspect ratio of the bounding box containing these pins) and/or estimated route 1626 further determines that the primary direction should be vertical (and thus that the connection should be primarily routed on a layer that uses vertical wiring as its primary direction.

Referring back to FIG. 15, after selecting a routing model for the selected connection, the process 1500 removes (at 1520) any pin protections created for the connection and performs a path search using the selected routing model and associated grid (i.e., the grid associated with the routing model) to attempt to identify a route within the length constraint (if any). After the router selects the routing model including the direction of wiring (PD or NPD as well as the particular primary direction for the route), the router is able to perform a path search using the routing model. Before doing so, the router removes all pin protection (if any) made for the pins and/or subnets of the connection such that a route is able to be made for the connection.

The router in some embodiments explores piecewise linear and/or curvilinear routes (if curvilinear routing is allowed) during its path search in the direction or directions specified by the selected routing model. In some embodiments, the router performs path searches and identifies route segments (i.e., wire segments) on all available interconnect layers for the connection. Thus, for NPD-designated connections, the router performs path searches on the lower NPD interconnect layers of the IC design. Due to the length constraint on these lower NPD interconnect layers (to avoid excessive resistance along the route), the router attempts to identify a route within the specified length constraint. For PD-designated routes, the router performs path searches on the upper PD interconnect layers of the IC design. Because there is no length constraint on the upper PD interconnect layers, the router does not have to identify a route within a length constraint on these interconnect layers (though the router will typically attempt to identify shorter routes when possible).

The process 1500 then determines (at 1525) whether the path search was successful and a route was identified for the selected connection. A route may not be able to be defined for a connection because of obstacles (e.g., other pins, other connections that were already routed) blocking potential routes for the connection. A route may not be able to be defined because the shortest available route for the connection violates a length constraint defined in the first design rule set.

If the process 1500 determines that the path search was not successful, the process 1500 returns (at 1530) a routing failure and adds the connection to the PD router list if necessary. In some embodiments, when a router is unable to identify a route for an NPD-designated connection, the router redesignates the connection for PD routing and adds the connection to the list of PD-designated connections for subsequent routing on an upper PD interconnect layer.

Though not shown in this figure, if no route for a PD-designated connection can be identified (during routing of the PD-designated connections), in some embodiments the router removes one or more previously defined routes for one or more other connections and returns to performing path searches for the selected PD connection to again attempt to identify a route for that connection.

If the process 1500 determines that the path search was successful and a route was identified, the process 1500 determines (at 1505) whether the selected connection’s associated net has been fully routed. If the process 1500 determines that the connection’s net is fully routed (i.e., that all connections for the net have been routed), the process 1500 removes (at 1540) all pin protections for the net and all unused partial routes for the net. In some embodiments, as routes are defined for connections of a net, some pin protection remains, and some partial routes (e.g., route guides) that were initially created are not used. In such embodiments, the router removes all of this, as the entire net is fully routed and no longer needs this pin planning in place.

If the process 1500 determines that the connection’s associated net is not fully routed (i.e., that at least one other connection of the net has not yet been routed), the process 1500 examines (at 1545) the current pin planning and protection for the connection to determine whether to modify pin planning and protection for the net’s connection(s). As at least one connection of the net has now been routed, the router in some embodiments performs dynamic pin planning and protection to ensure that other connections of the net can be routed to the already routed connection(s). In some embodiments, this includes protecting locations along the routed connection (i.e., the subnet) to ensure that other nodes of the net can be routed to the subnet.

Lastly, the process 1500 determines (at 1550) whether the selected connection is the last unrouted connection (or at least the last unrouted NPD-designated connection) for the IC design. If additional connections (or at least NPD-designated connections) remain to be routed, the process 1500 returns to 1505 to select another connection. Once all of the connections (or at least all of the NPD-designated connections) have been routed, the process 1500 ends.

Because the process 1500 describes defining routes on a per-connection basis, in some embodiments one net is routed on different wiring layers. For example, in some embodiments a first connection of a net is routed on an NPD wiring layer using a first routing model while a second connection of the net is routed on a PD interconnect layer using a second routing model. These two route segments of the net are connected by one or more multi-layer interfaces (e.g., one or more vias from the NPD interconnect layer, through any intervening NPD or PD interconnect layers, and to the PD interconnect layer).

The above-described process 1500 describes using characteristics (e.g., estimated wire length, node positional relationship, etc.) of a connection to select a routing model for routing the connection. The process 1500 also describes performing dynamic pin planning and protection on connections during routing. Conjunctively or alternatively, static pin planning and pin protection is performed in some embodiments on connections before any routes for connections are defined. Static pin planning and protection are performed in some embodiments to preemptively protect connections’ routes from being blocked by other connections’ routes (i.e., to ensure that pins on a route have access (though z-axis connections) to upper layers on which their routes are defined).

FIG. 17 conceptually illustrates a process 1700 for performing static pin planning for a set of connections of an IC design. This process 1700 is performed in some embodiments by a router (e.g., an NPD router or a router that defines routes on NPD and PD layers) after the connections have been designated as PD connections and NPD connections. In some embodiments, this process 1700 is performed for both PD and NPD connections of an IC design, which will be described below. However, in other embodiments, this process 1700 is performed only for PD-designated connections to protect the pins of these routes during routing of the NPD-designated connections.

The process 1700 begins by selecting (at 1705) a connection. As mentioned, these may only include PD-designated connections or may include all of the connections. Some embodiments select the routes randomly, or in order from, e.g., longest to shortest route (or vice versa).

For the selected connection, if necessary, the process 1700 performs (at 1710) a pin protection operation to define one or more obstacles to protect one or more nodes of the selected connection. The router in some embodiments examines a connection’s nodes (pins and/or subnets) to determine whether pin protection is necessary. In some embodiments, the router examines the nearby pin density (i.e., the density of other pins around the connection’s nodes) and/or the Gcell density (i.e., the global route density of the Gcell(s) in which the connection’s nodes reside). If the router determines that pin protection should be performed for one or both of the connection’s nodes (i.e., if the nearby pin density and/or Gcell density passes a threshold), the router performs pin protection for one or both of the nodes.

When the selected connection is a PD-designated connection, the router in some embodiments defines obstacles on the lower NPD layers above one or more nodes (e.g., pins and/or subnets) of the connection. For example, in an IC design that has lower NPD layers for metal layers 1-3 and upper PD layers for metal layers 4 and up, the router in some embodiments defines an obstacle (e.g., an artificial boundary) on each of the metal layers 1-3 above a pin of a PD-designated connection. An obstacle defined in a location ensures that no route for an NPD-designated connection will be defined through that location on any of the metal layers for which the obstacle is defined unless the obstacle is removed. As such, in later routing of the PD-designated connection, a vertical via stack can be defined for that PD-designated connection at the location so that a route can connect from the pin, through the via stack, to any of the upper PD layers. In some embodiments, the router also defines one or more obstacles on a subset of one or more upper PD layers to ensure that the route for the PD-designated connection can be defined on any of the subset of PD layers. For instance, if the connection is likely to use vertical PD wiring, then the router might define an obstacle on any non-vertical (e.g., horizontal) PD layers below a given vertical PD layer.

When the selected connection is an NPD-designated connection, the router in some embodiments defines obstacles on one or more of the lower NPD layers above one or more nodes of the connection. For example, in the same IC design mentioned above (with lower NPD layers as metal layers 1-3), the router in some embodiments defines an obstacle on metal layer 1 (M1) above a pin of the NPD-designated connection such that no other route can be defined through that location on M1 before this NPD-designated connection. As such, the NPD-designated connection can be routed directly on M1, or a via can be created at the location up to metal layer 2 (M2) to route the connection on M2. Even though pin protection was not made on M2 to ensure a via can be made directly up to M3, the connection can still be routed on M3 in some embodiments as long as a defined route does not block such a via up to M3. The router can define obstacles for nodes (pins and/or subnets) of a connection on any number of metal layers. In some embodiments, rather than defining one or more obstacles to later define one or more vias, the router defines the one or more vias during the pin protection operation. In such embodiments, the vias are defined during pin protection before their associated route segments are defined.

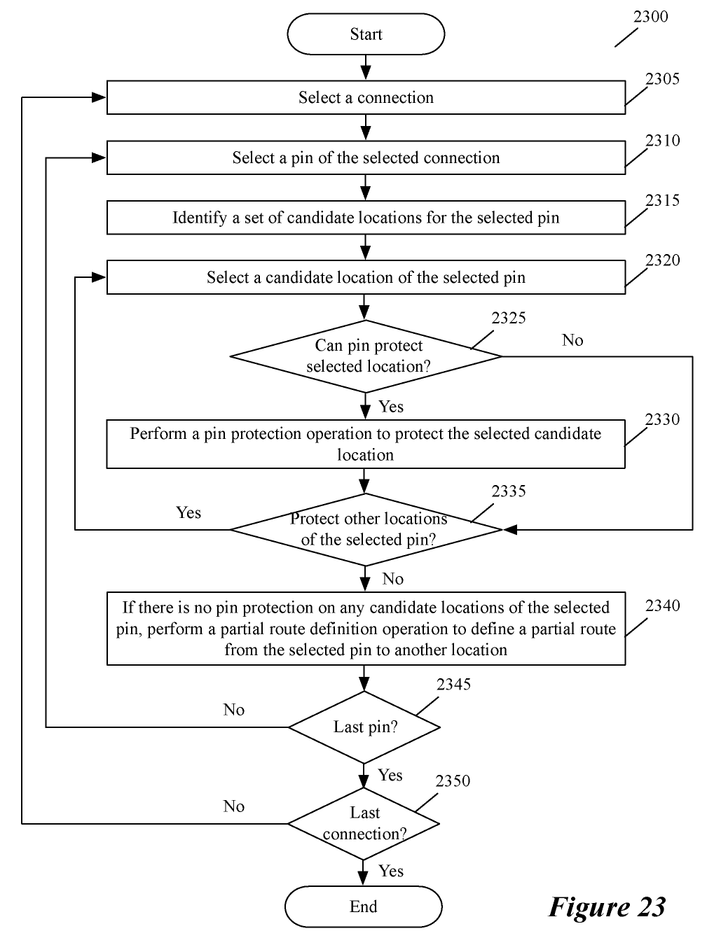

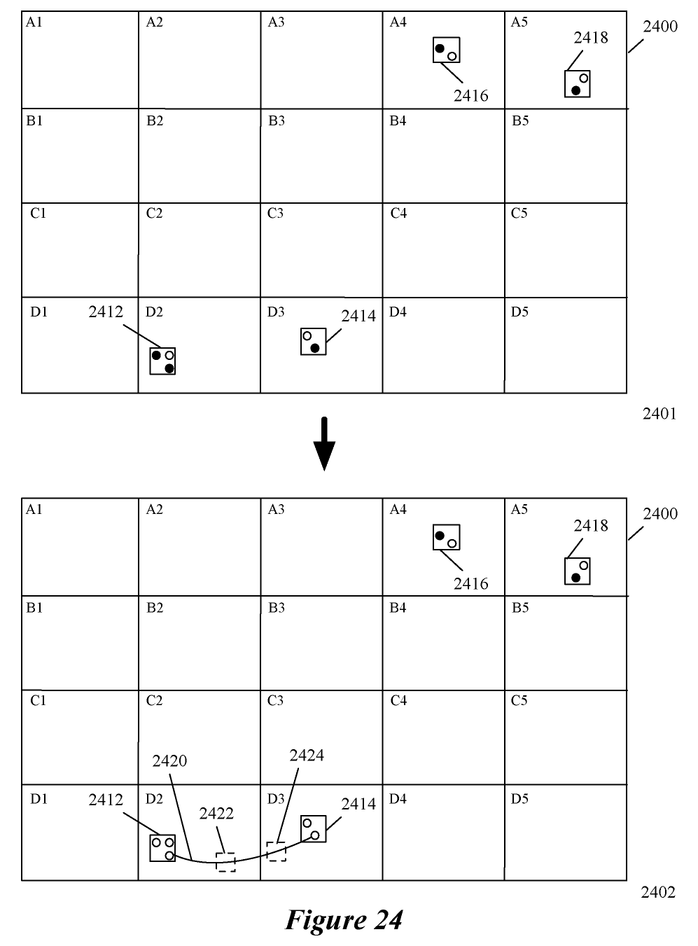

In some embodiments, rather than defining obstacles that are the size of an entire node (e.g., the size of an entire pin, or an entire subnet during dynamic pin protection), the router defines obstacles on one or more candidate connection locations of a node. Candidate connection locations of a node are locations on the node at which a route can optimally end to connect to the node. As such, the router in some embodiments defines one or more obstacles at locations above one or more candidate locations of a node to protect the node. Further information regarding protecting candidate connection locations of a node (pin or subnet) will be described below in relation to FIGS. 23-24.

At 1715, the process 1700 determines whether any node of the selected connection needs a partial route (also referred to as a route guide or virtual pin) defined (or is likely to benefit from the definition of a partial route). In some embodiments, the router performs a via stack validation operation to determine whether a vertical via stack is feasible for the connection. In certain cases, a pin or subnet of a connection that will need to connect to another layer using a via stack cannot be routed using a vertical via stack (e.g., due to congestion of pins, congestion of Gcells defined during global routing, other routes of other connections, etc.). In some such cases, the router determines that a partial route should be defined for the node.

If a partial route is needed for one or more nodes of the connection, the process 1700 defines (at 1720) a partial route for the node or nodes that require (or would likely benefit from) the partial route. The router in some embodiments defines a partial route from the node to another location on the same metal layer as the node such that a stack of one or more vias from that other location can be created to a different metal layer on which the rest of the connection can be routed. That is, the router defines a virtual pin at a different location on the same metal layer as the node and then defines a route (e.g., a straight-line route, a PWL route, or a curvilinear route) from the node to the virtual pin within the metal layer. Using such a partial route allows at least a portion of a route to be defined for the connection on another layer when a vertical via stack for the connection is not feasible.

After defining the partial routes for the connection (or if no partial routes are needed for the connection because the connection does not need a via stack or a vertical via stack will be possible for the connection, the process 1700 determines (at 1725) whether the selected connection is the last connection. If additional connections remain for pin planning and protection, the process 1700 returns to 1705 to select another connection and perform pin planning and protection for that connection. Once all connections have been processed, the process 1700 ends.

As mentioned above, some embodiments determine whether pin protection of a connection’s node is necessary by examining the pin and/or Gcell density around the node. Some embodiments determine whether to protect a node by examining the pin and/or Gcell densities against a threshold density value (e.g., 0.7 or 75%, 0.8 or 80%, 0.9 or 90%, etc.). In some embodiments, if the pin density is above the threshold value, the node will be protected. Conjunctively or alternatively, in some embodiments, if the Gcell density is above the threshold value, the node will be protected. If both density values are below the threshold, then the router does not define any protection for the node on the assumption that the node will be routable without that protection.

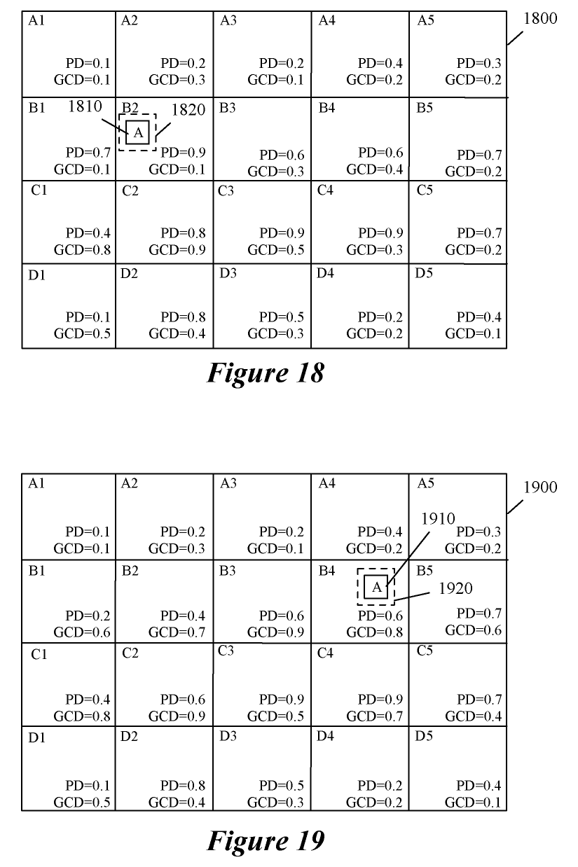

FIGS. 18-19 illustrate two examples of pin protection performed for pins 1810 and 1910 based on pin density and Gcell density. This pin protection is performed to define obstacles on one or more metal layers above the location of these pins 1810 and 1910.

FIG. 18 illustrates an example Gcell grid 1800 with a pin 1810 residing in Gcell B2. Each Gcell of the grid 1800 is labeled with its corresponding pin density and Gcell density. The pin density of each Gcell indicates the level of congestion of pins within that Gcell, and the Gcell density of each Gcell indicates the level of congestion of Groutes within that Gcell (with 1.0 being the max density for each of these measures).

In this example, the pin 1810 is in a Gcell with a high pin density (0.9). While the Gcell density is low (0.1), the high pin density indicates that the pin 1810 should be protected in order to ensure that a route can be made to this pin 1810. That is, in some embodiments, Gcell density does not need to be considered when determining if pin protection is needed if the pin density alone is high enough to warrant pin protection. As such, the router defines an obstacle 1820 around the pin 1810 on one or more metal layers above the layer on which the pin is located. Determining which metal layers to define these obstacles is in some embodiments based on whether the pin is a pin for an NPD-designated connection or for a PD-designated connection. For instance, if the pin 1810 is for an NPD-designated connection, then the obstacle 1820 only needs to be defined on some or all of the lower NPD metal layers (e.g. layers M1 or M1-M2). On the other hand, if the pin 1810 is for a PD-designated connection, then obstacle 1820 may be defined on all of the lower NPD metal layers and potentially one or more of the upper PD metal layers.

FIG. 19 illustrates another example Gcell grid 1900 with a pin 1910 residing in Gcell B4. As with the example above, each Gcell of this grid 1900 is labeled with its pin density and Gcell density. In this example, the pin 1910 is in a Gcell with a moderate pin density (0.6), which does not necessarily indicate that the pin needs to be protected. Some embodiments define a threshold pin density value (e.g., 0.8, 0.9) at or above which pin protection is always used. In this case, the Gcell’s pin density of 0.6 falls below the threshold pin density. If using a lower pin density (e.g., 0.5), then the pin density itself would indicate that the pin 1910 qualifies for pin protection.

Even though the pin density of Gcell B4 is not sufficiently high to qualify the pin 1910 for automatic pin protection, because the Gcell density is high (0.8), the router determines that the pin 1910 should be protected (e.g., because this density exceeds the defined threshold density value) and thus defines an obstacle 1920 around the pin 1910 on one or more metal layers (using the same criteria indicated above for pin 1810 as to on which metal layers the obstacle is defined).

The above FIGS. 18 and 19 describe comparing pin density and Gcell density to a threshold density value to determine whether to perform pin protection. In some embodiments, one threshold density value is used for both pin density in Gcell density (i.e., the router compares both density values to one threshold value of and if either density value is above this threshold, then an obstacle is defined). Other embodiments use different threshold values for pin density and Gcell density (e.g., with the pin density threshold higher than the Gcell density threshold or vice versa). If either of these thresholds are surpasses, the router defines an obstacle. Still other embodiments use a threshold for the combined Gcell and pin density values (e.g., 1.4, 1.5, etc.), such that if the combined Gcell and pin density values are over the threshold. Some such embodiments use a high individual threshold for pin density and Gcell density (e.g., 0.8, 0.9), but also a combined threshold (e.g., 1.4). If any of the individual pin density or Gcell thresholds, or the combined threshold, is surpassed, then the router defines an obstacle. This last option ensures that pin protection is used if either Gcell density or pin density is very high (even if the other is quite low) or if both Gcell density and pin density are moderately high (even if neither is very high).

In some embodiments, rather than defining the obstacles 1820 and 1920, some embodiments define the actual via(s) above the pins 1810 and 1910 (which then function as obstacles during router of other routes). In such embodiments, the vias are defined during pin protection, such that they do not need to be later defined when the rest of the routes are defined.

As described above, some embodiments define a partial route from a node to another location on one layer (e.g., by defining a virtual pin at that location and a route guide from the node to the virtual pin) such that a via stack can be created from that location on the layer to another layer to complete the route for the connection. When a via stack directly up from the node is likely or decidedly not feasible (i.e., pin protection cannot be used), some embodiments use this technique instead.

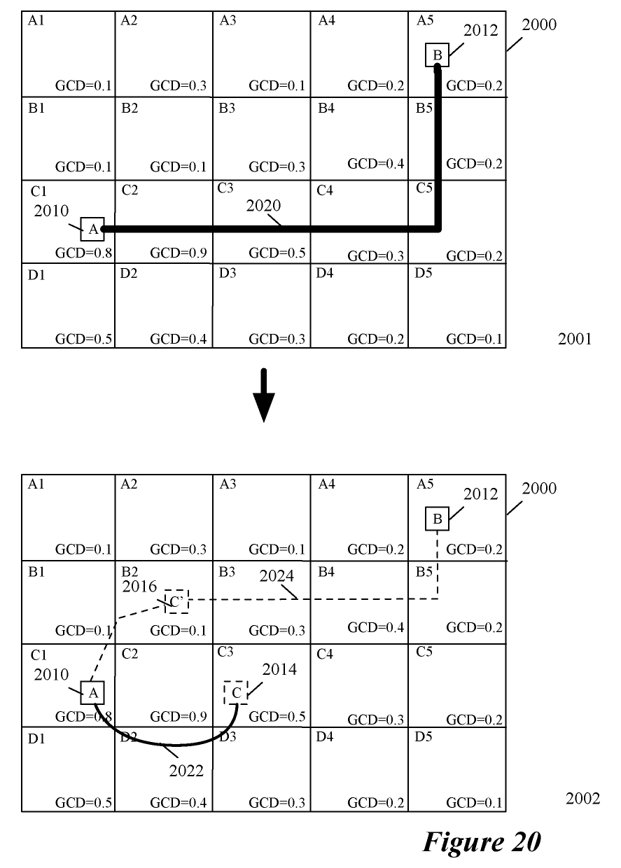

FIG. 20 illustrates the definition of a partial route 2022 for a connection of two pins 2010-2012. This partial route 2022 is defined in order to avoid high density areas surrounding one of the pins 2010 of the connection. As shown, the pin 2010 resides in Gcell C1 and pin 2012 resides in Gcell A5 of a Gcell grid 2000 created during global route definition of the connection.

At stage 2001, a global route 2020 is defined between the two pins 2010-2012. This global route 2020 is defined to traverse from Gcell C1 containing pin 2010, through Gcells C2-C5 and B5, and to Gcell A5 containing pin 2012. However, pin 2010 resides in a Gcell of high Gcell density (0.8), and the global route 2020 traverses another Gcell of high density (0.9). Such a high-density area indicates that a vertical via stack above pin 2010 may not be possible (e.g., as one or more other routes defined before this connection’s route may block such a via stack). To avoid these areas of high density, the router of some embodiments defines a partial route.

At stage 2002, the router defines a partial route 2022 from pin 2010 to a virtual pin 2014. This partial route 2022 avoids the high density Gcell C2 and ends at the virtual pin 2014 which is in a Gcell C3 that has a lower density and is still along the global route 2020. The global route 2020 is not shown in stage 2002 for simplicity. By creating this partial route 2022, a router is more easily able to avoid blockages when defining a route from pin 2010 to 2012.

Rather than defining the partial route 2022 along the global route 2020, some embodiments define a different partial route to a virtual pin 2016 that follows a different optional global route for the connection. In such embodiments, the route between the pins 2010-2012 no longer follows the global route 2020 but still avoids the high density Gcell C2.

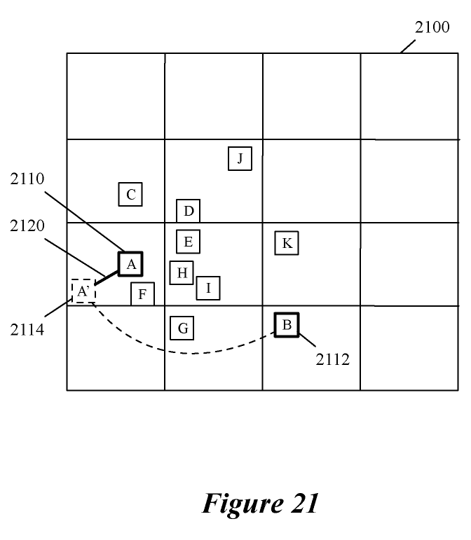

In addition to (or as an alternative to) defining partial routes based on Gcell density, some embodiments define partial routes based on pin density and/or pin position. FIG. 21 illustrates an example connection of pins 2110-2112 for which a partial route 2120 is defined. In this example, the connection includes two pins 2110-2112. However, a partial route can also be created for a connection between a pin and a subnet or a connection between two subnets. As shown, the pins 2110-2112 reside on a grid 2100 along with multiple other pins of multiple other connections.

Pin 2110 is in an area of high pin density, without a clear (e.g., straight) path directly to pin 2112. One or more other routes defined for any of the neighboring pins may block this connection from being made. To avoid encountering such a blockage, a router in some embodiments defines the partial route from pin 2110 to a virtual pin 2114. A clearer path to pin 2112 exists from the virtual pin 2114, as this virtual pin 2114 is further from the neighboring pins than pin 2110.

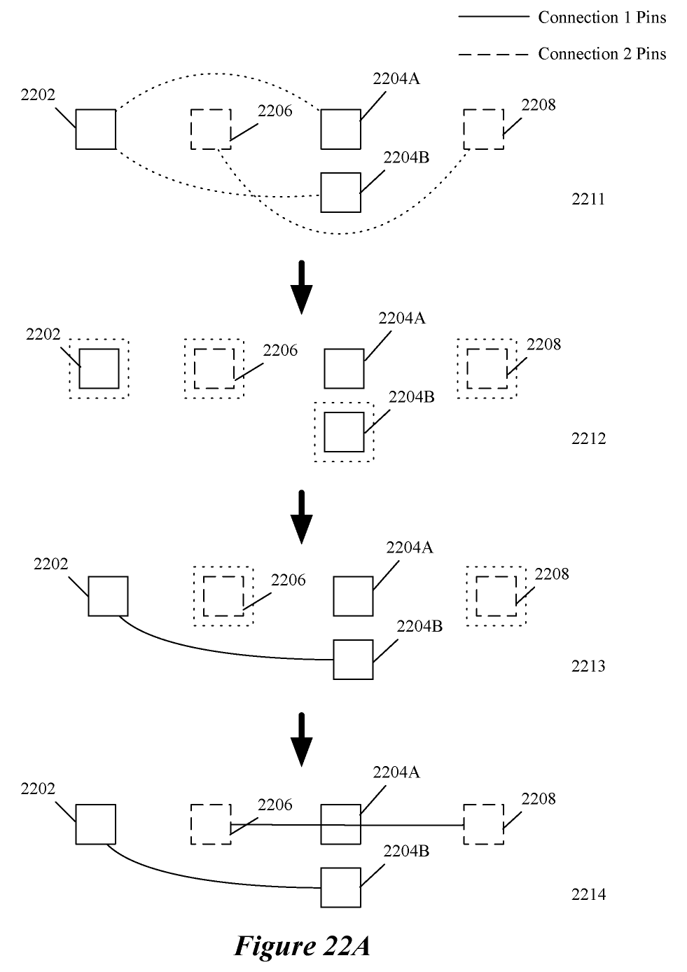

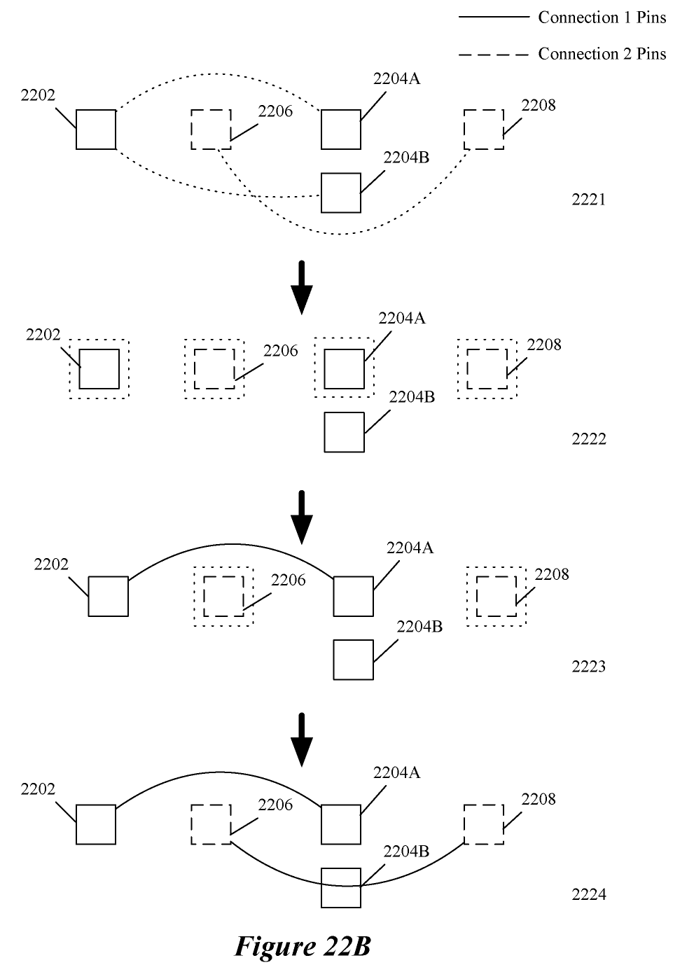

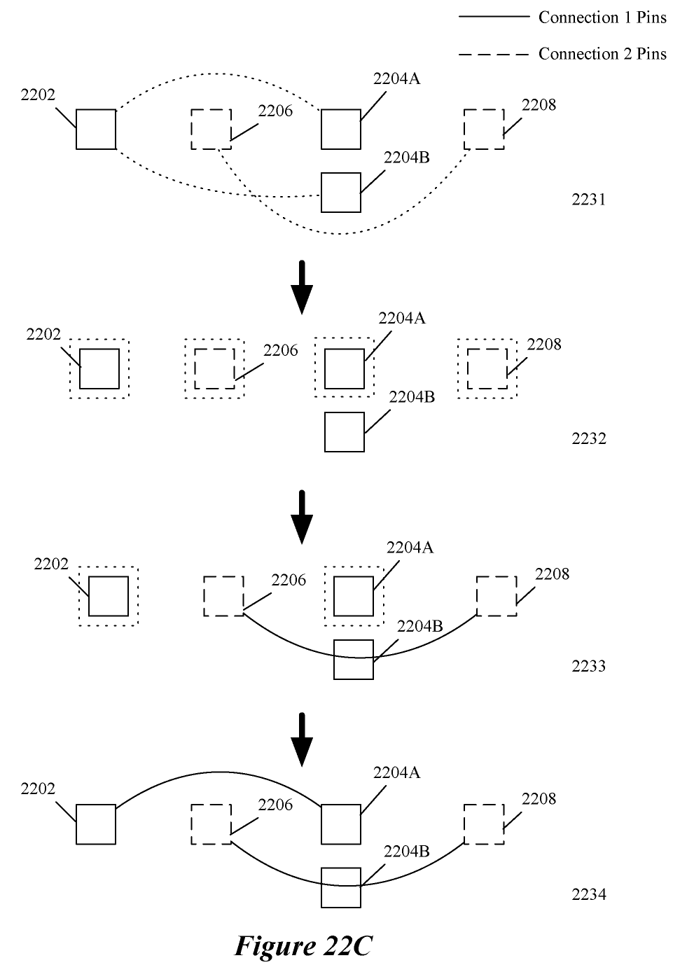

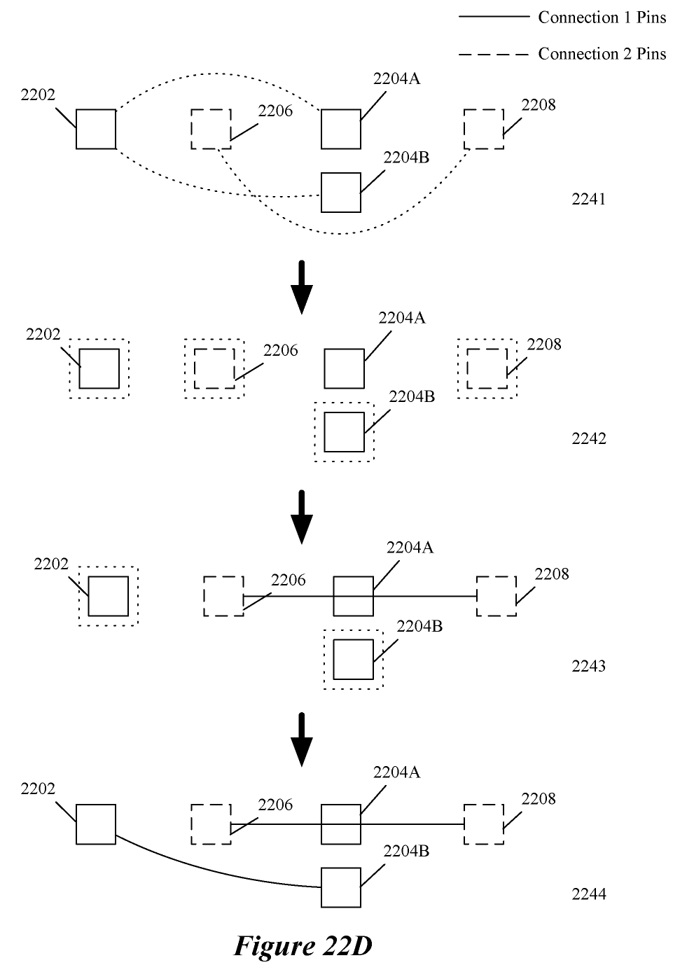

As mentioned above, when pin protection is in place for one or more nodes of a connection, the router removes this pin protection before routing the connection. FIGS. 22A-D illustrate different examples of pin protection removal performed during routing of two separate connections. The pin protection that is to be removed includes, for each node, one or more obstacles defined on locations above the node on one or more metal layers. As shown in each of these figures, connection A includes pins 2202-2204 while connection B includes pins 2206-2208. Pin 2204 of connection A has two candidate connection locations 2204A and 2204B to which the connection can be made.

FIG. 22A illustrates, at stage 2211, that pin 2202 of connection A needs to be connected to either pin location 2204A or 2204B, and that pin 2206 of connection B needs to be connected to pin 2208. At stage 2212, pin protection has been added to pin 2202, pin location 2204B, pin 2206, and pin 2208. As only one of the pin locations 2204A or 2204B needs to be used to route connection A, only one location needs to be protected. However, in other embodiments, both locations 2204A-B are protected.

At stage 2213, the router routes connection A first (i.e., prior to connection B). As such, the router removes pin protection from pin 2202 and pin location 2204B and defines a route from pin 2202 to pin 2204B (in this case, a curvilinear route). At stage 2214, the router routes connection B. Because pin location 2204A was not used to route connection A, no pin protection is needed for this pin and at stage 2214 the router routes connection B over this location (i.e., using the shortest available path between the two pins 2206-2208).

The first stage 2221 of FIG. 22B is the same as FIG. 22A, showing that pin 2202 of connection A needs to be connected to either pin location 2204A or 2204B, and that pin 2206 of connection B needs to be connected to pin 2208. At stage 2222, pin protection has been added to pin 2202, pin location 2204A, pin 2206, and pin 2208. As only one of the pin locations 2204A or 2204B needs to be used to route connection A, the router only protects one location in some embodiments. In FIG. 22A, the other pin location (2204B) was protected. Different embodiments may use different techniques to select which pin should be protected. Some embodiments select randomly between two or more candidate pins, while other embodiments use a metric (e.g., protecting the candidate pin located in the lowest pin density area or in the highest pin density area).

At stage 2223, the router routes connection A first. As such, the router removes pin protection from pin 2202 and pin location 2204A, then defines a route between pin 2202 and pin location 2204A (in this case, a curvilinear route that avoids the protected location above pin 2206). At stage 2224, the router routes connection B. Because pin location 2204B was not used to route connection A, no pin protection is needed for this pin and at stage 2224 the router routes connection B over this location (i.e., using the shortest available path between the two pins 2206-2208, which in this case is a curvilinear path over pin location 2204B).

The first stage 2231 of FIG. 22C is the same as FIG. 22A, showing that pin 2202 of connection A needs to be connected to either pin location 2204A or 2204B, and that pin 2206 of connection B needs to be connected to pin 2208. At stage 2232, the router adds pin protection to pin 2202, pin location 2204A, pin 2206, and pin 2208. As only one of the pin locations 2204A or 2204B needs to be used to route connection A, the router only protects one location in some embodiments.

At stage 2233, the router routes connection B first. As such, the router removes pin protection from pins 2206 and 2208, then defines a route between these two pins (in this case, a curvilinear route that avoids the protected pin location 2204A). At stage 2224, the router routes connection A. Because pin location 2204B was not protected, the route for connection B passes over this location, so pin location 2204A is used for the route for connection A (a curvilinear path between pin 2202 and pin location 2204A that avoids pin 2206.

The first stage 2241 of FIG. 22C is the same as FIG. 22A, showing that pin 2202 of connection A needs to be connected to either pin location 2204A or 2204B, and that pin 2206 of connection B needs to be connected to pin 2208. At stage 2242, the router adds pin protection to pin 2202, pin location 2204B, pin 2206, and pin 2208. As only one of the pin locations 2204A or 2204B needs to be used to route connection A, the router only protects one location in some embodiments.

At stage 2233, the router routes connection B first. As such, the router removes pin protection from pins 2206 and 2208, then defines a route between these two pins. Because pin location 2204A is not protected, the router can define a straight-line route between pins 2206 and 2208 that passes over pin location 2204A. At stage 2224, the router routes connection A. Because pin location 2204A was not protected, the route for connection B passes over this location, so pin location 2204B is used for the route for connection A (a curvilinear path between pin 2202 and pin location 2204B.

As mentioned above, when a pin has multiple candidate connection locations for a pin (or other node, such as a subnet), different embodiments may use different algorithms to determine which of the candidate locations to protect. FIG. 23 conceptually illustrates a process 2300 of some embodiments for protecting candidate locations of different pins of connections, though it should be understood this can apply to different candidate locations for connecting to a subnet. The process 2300 is performed by a router that defines routes for an IC design. In some embodiments, as described above, an NPD router defines routes for the IC design while a PD router defines routes for the IC design after routing for the NPD-designated connections is complete. In some such embodiments, the NPD router performs the process 2300 for the NPD-designated routes as well as PD-designated routes (which need pin protection so they can be successfully routed later by the PD router). The PD router may also perform the process 2300 if needed (e.g., if the pin protections defined by the NPD router do not carry over to the PD router). Alternatively, in other embodiments, a single router defines routes for both the NPD-designated connections and the PD-designated connections (i.e., performs routing for all wiring layers of the IC design). The process 2300 is performed in some embodiments after the connections of nets have been classified into PD connections and NPD connections.

The process 2300 begins by selecting (at 2305) a connection of the IC design and selecting (at 2310) a pin of the selected connection. Some embodiments select connections in the order that they will be routed (e.g., from shortest to longest connection), while other embodiments select connections in the opposite order (e.g., from longest to shortest connection, initially protecting the nodes of the last connection to be routed). Still other embodiments use different algorithms to select the connections, such as randomly selecting connections or selecting from groups of connections. Similarly, some embodiments select the pins of a selected connection in a random order, use a left-to-right then top-to-bottom ordering for the pins (or different location-based ordering), or use another mechanism (e.g., sorting the pins based on the pin density and/or Gcell density of their location).

For the selected pin, the process 2300 identifies (at 2315) a set of one or more candidate locations. In some embodiments, one pin has one or more locations (commonly referred to as contact points) at which the pin can be optimally connected to a route (i.e., to an interconnect wire segment). When connecting this pin within the fabricated, any one of these locations can be used with equal (or effectively equal) functionality. As such, the router of some embodiments identifies the set of candidate locations for the selected pin to identify the locations at which the pin can be optimally connected. Different pins (of either the same or different connections) may have different numbers of candidate locations, and some pins may only have a single candidate location.

The process 2300 then selects (at 2320) a candidate location of the selected pin. Like the pin selection, the order of selection of the candidate locations may vary between different embodiments. Some embodiments select the candidate locations in a random order, use a left-to-right then top-to-bottom ordering for the candidate locations (or different location-based ordering), or use another mechanism (e.g., sorting the candidate locations based on their pin density and/or Gcell density.

After selecting a candidate location, the process 2300 determines (at 2325) whether the selected candidate location can be protected. In some embodiments, all candidate locations of one pin are allowed to be protected. In other embodiments, only a particular number (e.g., one) of candidate locations of one pin is allowed to be protected. In the latter case, the router determines how many candidate locations of the selected pin other than the selected candidate location are already protected. In different embodiments, each pin may have the same maximum number of protected candidate locations or different pins may have different maximum numbers of protected candidate locations.

In some embodiments, the router also verifies whether the selected candidate location can be protected based on whether a via stack is possible directly above the selected candidate location. The router performs a via stack verification operation to determine whether a vertical via stack from the candidate location up to a particular layer is possible (i.e., whether a vertical via stack would not be obstructed, such as by other pins). For example, if the selected candidate location is for a pin of a PD-designated connection, the router determines whether a via stack is possible through all of the lower NPD layers and up to at least the lowest of the PD layers. If the selected candidate location is for a pin of an NPD-designated connection, the router determines whether a via stack is possible up to at least one lower NPD layer. If the router can verify the vertical stack, the router can protect the candidate location. If the router cannot verify the vertical stack, then the router does not protect the candidate location as this protection would not actually ensure that a via stack will be possible for the selected pin when it comes time to route the pin and would thus unnecessarily introduce an obstacle for routing without the later benefit of that obstacle.

If the selected candidate location can be protected, the process 2300 performs (at 2330) a pin protection operation to protect the selected candidate location. The router, after determining that it can protect the selected candidate location, creates one or more obstacles (e.g., one or more artificial boundaries) above the selected candidate location on one or more layers above the candidate location, as described previously.

For example, if the router is protecting a candidate location of a PD-designated connection up through lower NPD metal layers 1-3, the router creates an obstacle above the candidate location on metal layers 1-3. In some embodiments, the router also creates an obstacle on one or more of the upper PD metal layers (e.g., on metal layer 4). If the router is protecting a candidate location of an NPD-designated connection through at least one of lower NPD metal layers 0-2, the router creates an obstacle above the candidate location on at least M0 and may also create an obstacle M1 and/or M2.

The process 2300 then determines (at 2335) whether other candidate locations of the selected pin should be protected. As mentioned above, in some embodiments, only a particular number (e.g., one, two) of candidate locations of one pin are allowed to be simultaneously protected. In some such embodiments, the router determines whether the maximum number of candidate locations of the selected pin have been protected. If this maximum number is reached, the router cannot protect any more candidate locations of the selected pin and thus there is no need to examine any other candidate locations for the selected pin. If the maximum number of protected candidate locations has not yet been reached (and additional candidate locations remain to be selected), then the process 2300 returns to step 2320 to select another candidate location of the selected pin.

Once all of the candidate locations for the selected pin have been examined and/or the maximum number of protected candidate locations has been reached, then if no pin protection has been put in place for any candidate locations of the selected pin, the process performs (at 2340) a partial route definition operation to define a partial route from the selected pin to another location. If the router was not able to protect any candidate locations of the selected pin (e.g., if no candidate location’s via stack was able to be verified), the router in some embodiments performs the partial route definition operation such that a route from this pin can be made using the partial route. As described previously, the defined partial route is a partial route on the same metal layer as the selected pin and is defined from the pin to a different location (a virtual pin) on the metal layer. Because there is no pin protection in place to ensure a viable vertical via stack for the pin to the wiring layer on which a route will be defined for the pin, the router defines a partial route so that a via stack will be possible at the location at which the partial route ends (at the virtual pin location). In some embodiments, after defining the partial route, the router also protects the location at which the partial route ends so that a via stack can be made at that location.

The process 2300 then determines (at 2345) whether the selected pin is the last pin for the currently selected connections. The router determines whether all pins (e.g., all of one pin, all of two pins) of the selected connection have been selected. If additional pins of the connection remain for pin protection and planning analysis, the process 2300 returns to step 2310 to select another pin.

Once pin protection and planning has been performed for all of the pins of the current connection, the process 2300 determines (at 2350) whether the selected connection is the last connection. If additional connections remain, the process 2300 returns to 2305 to select another connection. Once all of the connections have been selected and the pins of those connections processed, the process 2300 ends.

The process 2300 is performed in some embodiments to ensure that each connection can be routed on one of the wiring layers designated for that connection. For example, some embodiments route as many NPD-designated connections as possible on the lower NPD metal layers before routing the PD-designated connections on upper PD layers, so protecting pins of PD-designated connections ensures that the NPD routing operation on the lower NPD metal layers does not completely block any of the PD-designated connections from being routed on the upper PD metal layers. Protecting pins of NPD-designated connections also ensures that they are able to be routed on the lower NPD metal layers.

In addition, while the process 2300 above is described in relation to performing pin protection on pins, these pin protection operations can also be performed for subnets in some embodiments. For example, multiple locations along a subnet (e.g., any pins at the ends of the subnet, intermediate locations between these pins) may be candidate locations for protection. Furthermore, while the process 2300 is described above in relation to protecting pins on a per-connection basis, some embodiments perform this pin protection on a per-net basis. In this case, the router selects through pins (and/or subnets) of one net at a time to protect candidate locations of the nets’ pins.

FIG. 24 illustrates a two-stage example of pin protection performed for a net including pins 2412-2418. In this example, pin protection is performed for two pins 2412-2414 and a subnet 2420 of the net, although in other embodiments, pin protection (or at least static pin protection prior to routing) is performed only for pins. As shown, the net includes four pins 2412-2418. Pin 2412 has three candidate connection locations (as denoted by circles), and each of the pins 2414, 2416, and 2418 has two candidate connection locations.

At stage 2401, each of the pins 2412-2418 has at least one candidate connection location protected (as denoted by black circles). Pin 2412 has two candidate locations protected, and pins 2414, 2416, and 2418 each have one candidate location protected. For each protected candidate location, an obstacle (e.g., an artificial boundary) is defined on the metal wiring layer on which the candidate location resides, and in some cases also on at least one metal wiring layer above the candidate location. The protection on the candidate locations of the pins 2412-2418 may be placed before routing is performed for this net or for any nets or connections of the IC design (i.e., static pin protection). In other cases, at least one candidate location of at least one pin is added during routing (i.e., dynamic pin protection).

At stage 2402, the pin protection has been removed for pins 2412 and 2414 (that belong to a connection of the net) in order to connect these pins with a route 2420. To ensure completion of the four-pin net, a set of candidate locations 2422-2424 along this route 2420 are protected such that the pins 2416-2418 (or a subnet defined between pins 2416 and 2418) can be connected to the route 2420. In this example, two candidate locations 2420-2424 are protected along the route 2420, neither of which include the actual pins 2412 or 2414. Different embodiments may protect different numbers of locations (e.g., at different intervals) along such a subnet, in some cases including the pins themselves. The protection added to the route 2420 referred to as dynamic, as it is added during routing.

As mentioned above, some embodiments define a via stack from a pin up to another metal layer so that the pin’s route can be defined on that other metal layer. In some embodiments, a vertical stack is used (and the location of the pin may be protected such that the vertical stack can be defined). In some embodiments, another type of via stack may be used for a pin if necessary.

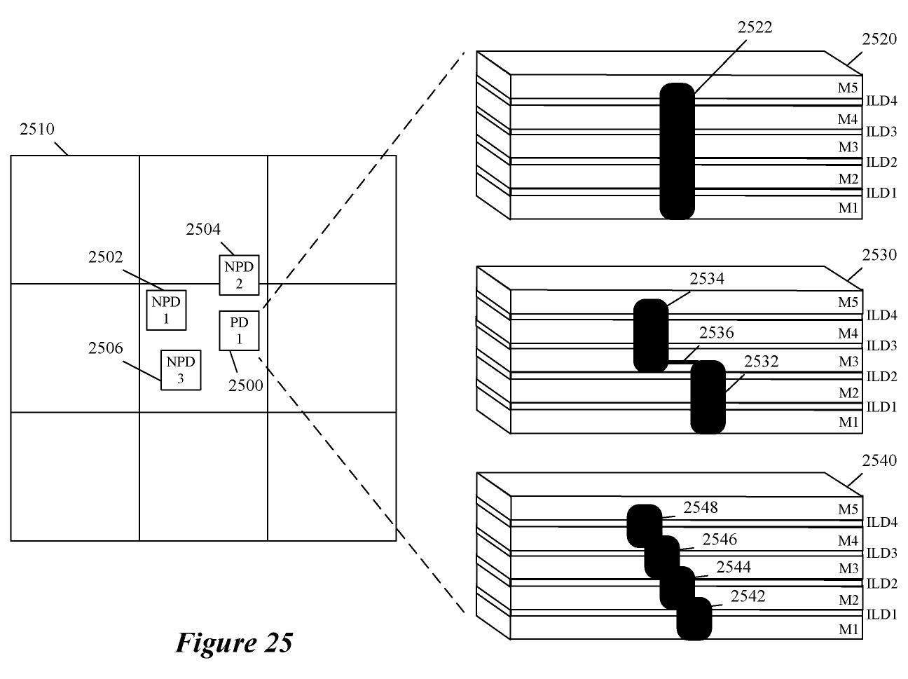

FIG. 25 illustrates an example pin 2500 of a PD-designated connection for which different via stacks can be defined (either during or prior to routing of the connection involving the pin. This pin 2500 may be a node of a pin/pin connection, or a node of a pin/subnet connection. As shown, the pin 2500 resides next to various neighboring pins 2502-2508 of NPD-designated connections on a grid 2510 of a first metal layer of an IC design. The pin 2500 is located on metal layer 1 (M1) in this example, and thus the via stack needs to traverse up from M1 to the layer on which the route for the pin 2500 will be defined.

Because the pin 2500 is a node of a PD-designated connection, a via stack is in some embodiments defined so that a route for the pin 2500 can be defined on one of the upper PD metal wiring layers. However, because of the high pin density in the area due to the NPD pins 2502-2508, some types of via stacks are more optimal than others, and some via stacks are not feasible. This figure illustrates three examples 2520, 2530, and 2540 of potential via stacks that can be defined from pin 2500 up to an upper PD metal layer.

The first example 2520 illustrates a vertical via stack 2520 from metal layer 1 (M1) up to metal layer 5 (M5) (traversing M2-4 and inter-layer dielectrics (ILDs) in between each of the metal layers). This vertical stack 2520 can be defined from the pin 2500 to M5 if there are no obstacles in the way of any vias in the stack 2520 on any of the metal layers.

The second example 2530 illustrates two separate via stacks 2532-2534 connected by a metal jog 2536 on metal layer 3 (M3). In this example, a first via stack 2532 is defined from M1 to M3, and then a metal jog 2536 is defined on M3 on the top of the via stack 2532 to a different location on M3. Then, a second via stack 2534 is defined at the end of the metal jog 2536 on M3 up to M5. In some embodiments, this type of via stack is defined to avoid an obstacle (e.g., on layer M4) that makes a vertical stack not optimal or not feasible.

The third example 2540 illustrates an offset via stack that includes four offset vias 2542-2546. In this example, the four vias 2542-2548 are offset from each other (i.e., the vias’ central axes are different) such that they do not create a vertical via stack (like via stack 2520). However, each via is sufficiently large and has sufficiently large overlap with its adjacent via(s) (e.g., the contacts of the via on the metal layers M4, M3, and M2 have sufficient overlap with the via holes in their neighboring inter-layer dielectrics) that the stack reaches up to M5 without needing a jog (i.e., a wire within one of the metal layers). Similar to the second example 2530, this type of via stack is defined in some embodiments to avoid an obstacle on one of the intervening metal layers that made a vertical stack not optimal or not feasible. Each of the three via stack examples can be defined during a node protection operation of a node.

Each metal layer of an IC in some embodiments uses a set of three grids on which metal wiring and vias are defined. In such embodiments, each metal layer includes (1) a down-via grid for defining vias to the metal layer below, (2) a planar grid for defining metal wiring on the metal layer, and (3) an up-via grid for defining vias to the metal layer above. In some such embodiments, the down-via grid of an upper metal layer and the up-via grid of an adjacent lower metal layer are the same, such that the two metal layers share one via grid between each other. In other embodiments, the two via grids are separate and are not shared between the two metal layers.

As described above, the grids of different layers often have a different pitch (i.e., different resolution). Specifically, the device layers have the finest pitch, lower NPD metal layers for interconnect wires have an intermediate pitch, and upper PD metal layers for interconnect wires have the largest pitch in some embodiments. As an example, a device layer on which one or more devices (e.g., transistors) are defined might have a first minimum pitch, a lower NPD layer could have a second minimum pitch no more than two times the first minimum pitch of the device layer, and an upper PD layer has a third minimum pitch more than two times the first minimum pitch. In some such embodiments, all device layers have a same first minimum pitch, all lower NPD layers (e.g., M0-M2, M1-M3, or M1-M4) have a same second minimum pitch, and all upper PD layers (e.g., M3+, M4+, M5+) have a same third minimum pitch. In other embodiments, each layer has a larger minimum pitch than the layer below it, even within a group of NPD layers or PD layers. In still other embodiments, the device layers and lower NPD metal layers have a same first minimum pitch while upper PD metal layers have a larger second minimum pitch.

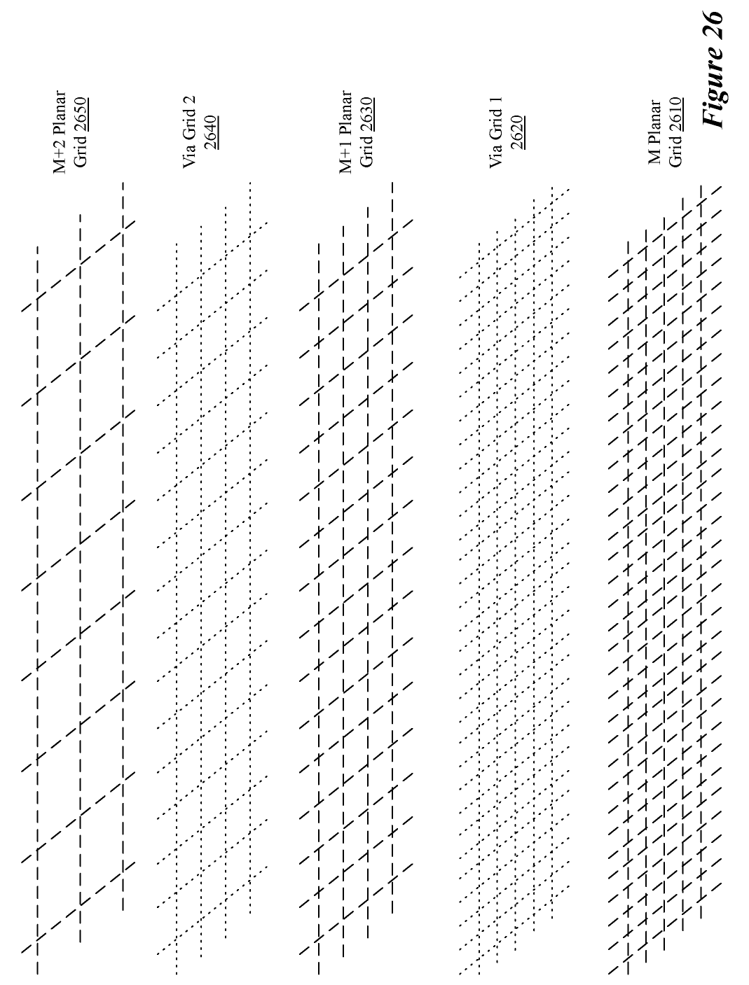

FIG. 26 illustrates an example set of grids 2610-2650 used for at least a portion of a metal layer stack. Each of these grids 2610-2650 has a pitch based on its corresponding layer, and as the stack goes up, grid pitch increases. As shown, the stack includes an M planar grid 2610 for metal layer M, a first via grid 2620 for the intervening layer between metal layers M and M+1, an M+1 planar grid 2630 for metal layer M+1, a second via grid 2640 for the intervening layer between metal layers M+1 and M+2, and an M+2 planar grid 2650 for metal layer M+2.

Metal layer M has its own planar grid 2610 for defining routes (e.g., wire segments) on that layer, and a via grid 2620 for defining vias to metal layer M+1. In some embodiments, metal layer M also has another via grid (not shown) below the planar grid 2610 for defining multi-layer interfaces (e.g., vias or contacts) to another layer below metal layer M (e.g., to a device layer or to metal layer M-1). The M planar grid 2610 has the smallest pitch of the grids shown in the figure. In this example, the first via grid 2620 has the same pitch as the M planar grid 2610.

Metal layer M+1 has its own planar grid 2630 for defining routes on that layer, the first via grid 2620 for defining vias to metal layer M, and the second via grid 2640 for defining vias to metal layer M+2. The pitch of metal layer M+1 is an intermediate pitch compared to the smaller pitch of metal layer M and the larger pitch of metal layer M+2. In this example, the second via grid 2640 has the same pitch as the M+1 planar grid 2630.

Metal layer M+2 has its own planar grid 2650 for defining routes on that layer, and the second via grid 2640 for defining vias to metal layer M+1. In some embodiments, metal layer M+2 also has another via grid (not shown) above its planar grid 2650 for defining vias to another metal layer above metal layer M+2, if layer M+2 is not the top metal layer of the IC design. The pitch of metal layer M+2 and its planar grid 2650 is the largest out of all shown grids 2610-2650.

In this example, the up-via grid for a metal layer has the same pitch as its planar grid (i.e., via grid 2620 has the same pitch as M planar grid 2610 and via grid 2640 has the same pitch as M+1 planar grid 2630). However, in other embodiments, each down-via grid for a metal layer has the same pitch as its associated planar grid (e.g., the via grid 2640 would have the larger pitch of M+2 planar grid 2650). In yet other embodiments, the pitch of a via grid is partway between the pitches of its two neighboring planar grids.

Wires or wire segments defined on the different planar grids 2610, 2630, and 2650 are of different thicknesses due to the different pitches of the grids. For instance, the smallest pitch M planar grid 2610 will have the thinnest wires, the M+1 planar grid 2630 will have intermediately thick wires, and the M+2 planar grid 2650 will have the thickest wires. Because the wires on the M planar grid 2610 are the thinnest, they also have the highest resistance. Due to this high resistance, the wires should not be longer than a threshold so as to avoid signal degradation.

When two adjacent metal layers have different pitches (i.e., different resolutions), their grids are considered misaligned. In addition, grids of adjacent layers can be misaligned if one of the grids is offset from the other, even if the grids have the same pitch. When creating a via between misaligned grids of two adjacent metal layers, some embodiments use an offset via. These offset vias may be created based on the lower grid pitch (i.e., using the smaller of the two pitches), with via pads (via contacts) that are long enough such that the upper via pad is large enough to fully overlap a grid location of the upper layer grid. In some embodiments, the hole or cut of the via between these two via pads is aligned with the lower via pad.

Rather than creating an offset via between two metal layers of different pitch, some embodiments create a via with a via pad (e.g., the upper via pad) that is off grid to its corresponding grid. That is, the upper via pad is off-grid to the upper metal layer’s grid and/or the lower via pad is off-grid to the lower metal layer’s grid.

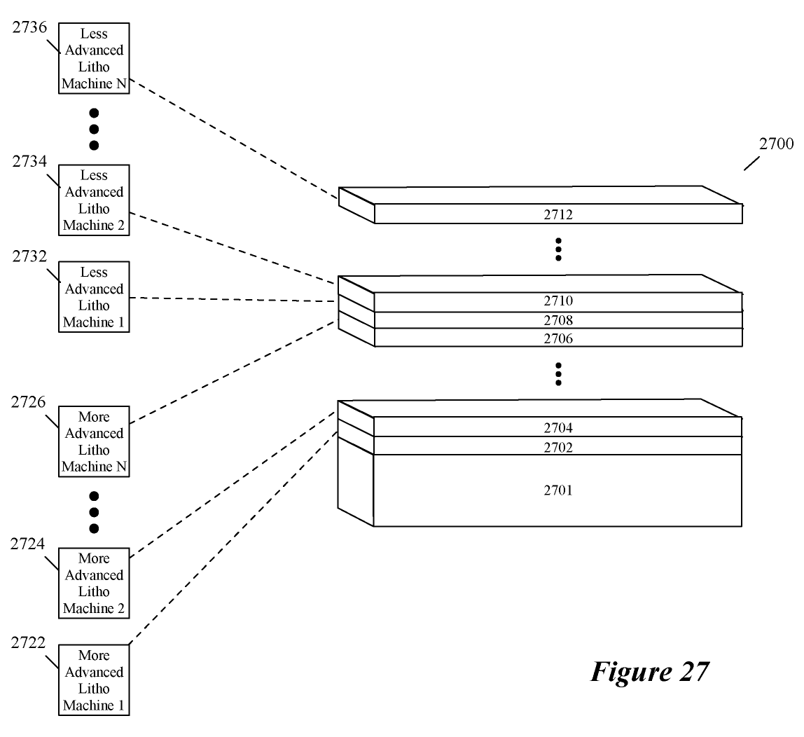

As indicated, the different pitches of different metal layers are often due to different types of lithographic machines being used to manufacture the different layers. For example, in some embodiments, one or more device layers and one or more lower NPD metal layers are manufactured using EUV lithographic machines (which produce a smaller pitch), while upper PD metal layers are manufactured using 193i lithographic machines (which produce a larger pitch). FIG. 27 illustrates an example IC 2700 manufactured using different sets of lithographic machines 2722-2726 and 2732-2736. As shown, the IC 2700 includes a substrate 2701, a device layer 2702 and a set of metal layers 2704-2712. The IC 2700 in some embodiments further includes metal layer 0 (M0), the first layer above the device layer 2702 in other embodiments.

A first set of more-advanced lithographic machines 2722-2726 manufactures the device layer 2702 and a first lower set of metal layers 2704-2706. In this example, the device layer 2702 and each of the lower metal layers 2704-2706 is manufactured using a different more-advanced lithographic machine (e.g., an EUV machine). In other embodiments, a single one of the more-advanced lithographic machines is used to manufacture at least two metal layers or the device layer and one or more of the metal layers. Furthermore, while this figure illustrates a single device layer 2702, in some embodiments the ICs may have multiple device layers, each of which may be manufactured using a different more-advanced lithographic machine or the same more-advanced lithographic machine.

A second set of less-advanced lithographic machines 2732-2736 manufactures the upper set of metal layers 2708-2712. In this example, each of the upper metal layers 2708-2712 is manufactured using a different less-advanced lithographic machine. As with the lower metal layers, in other embodiments, a single one of the less-advanced lithographic machines is used to manufacture at least two metal layers.

As described previously, the more-advanced lithographic machines 2722-2726 manufacture metal layers with a smaller pitch than the less-advanced lithographic machines 2732-2736. As such, these lower metal layers 2704-2706 can have a higher connection density (i.e., can have more wire segments closely packed together) than the upper metal layers 2708-2712, especially given the use of NPD wiring on the lower layers. By increasing the connection density in the lower metal layers, fewer layers need to be manufactured using the more-advanced lithographic machines (the use of which is typically more expensive), and fewer metal layers are needed overall thereby reducing the cost manufacturing the IC as a whole.

By optimizing the routing of the lower NPD metal layers, fewer layers are needed overall to complete the routing of the IC components. This allows for the ability to use the less-advanced lithographic machines 2732-2736 (which are less expensive than the more-advanced lithographic machines 2722-2726) to manufacture the upper PD metal layers 2708-2712 lower in the stack (i.e., to have fewer of the layers manufactured with the more-advanced lithographic machines).

Moreover, manufacturing finer-pitch NPD metal layers as intermediary layers between finer-pitch device layers and coarser-pitch upper PD metal layers allows for a smoother transition between the device layers and the upper PD metal layers. As the wires of the NPD metal layers have no preferred direction, the wires of these layers can (i) traverse any direction to connect with the device layers below at any location and (ii) traverse any direction to connect with the upper PD layers above at any location. Without intervening NPD metal layers, all of the components on the device layers would need to connect through the PD layers, which would likely entail a larger number of layers overall due to the greater limitations in routing imposed by preferred direction wiring.

It should be noted that in some embodiments the more-advanced lithographic technology (e.g., EUV) can also be used for a subset of the upper PD metal layers. For example, in some embodiments, a set of metal layers of an IC includes metal layers 0-6, with metal layers 0-2 being NPD metal layers manufactured using a more-advanced lithographic technology (e.g., EUV), metal layer 3 being a PD metal layer also manufactured using the more-advanced lithographic technology, and metal layers 4-6 being PD layers manufactured using a less-advanced lithographic technology (e.g., 193i). In this example, PD metal layer 3 can still have a higher connection density than PD metal layers 4-6 (due to having a smaller pitch), even though it still has a particular threshold amount (e.g., at least 50%) of wiring along a single preferred direction.

In addition, as described above, some embodiments use buried power rails in order to further increase connection density of the lower metal layers. Traditional power rails run along at least one of the lower metal layers (e.g., M1, M1 and M2), which greatly restricts the types of routes that are defined on those lower metal layers (as these power rails occupy space on the layers). Contrarily, buried power rails are placed below the metal layers and within the substrate, so they do not block any routes on any metal layers.

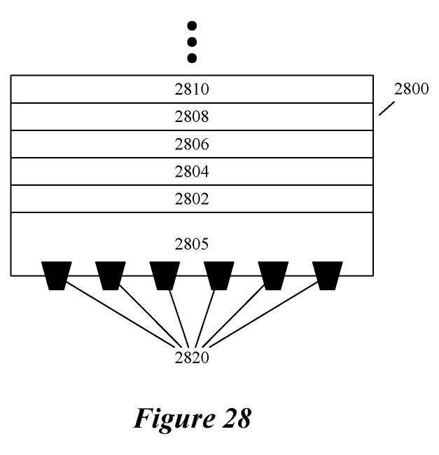

For instance, FIG. 28 illustrates an example IC 2800 with metal layers 2802-2810 and buried power rails 2820. In some embodiments, the IC 2800 has a set of lower NPD metal layers (e.g., M1-M2, M1-M3), and a set of upper PD metal layers (e.g., M3+, M4+). As shown, the buried power rails 2820 sit below all of the metal layers 2802-2810 within the substrate 2805 of the IC 2800. This allows for wiring made on the metal layers 2802-2810 to have freedom to be made in many directions, which traditional power rails do not provide.

For example, in some embodiments one or more of the lower metal layers (e.g., layer 2802, layers 2802-2804, layers 2802-2806, etc.) have wires that traverse in multiple (e.g., all) directions. Traditional power rails on layer 2802 or layers 2802-2804 would restrict both the directions of the routing on these layers as well as the space available for the routes. Because the power rails 2820 are buried within the substrate 2805, these layers 2802 and 2804 are completely free for wiring in any direction.

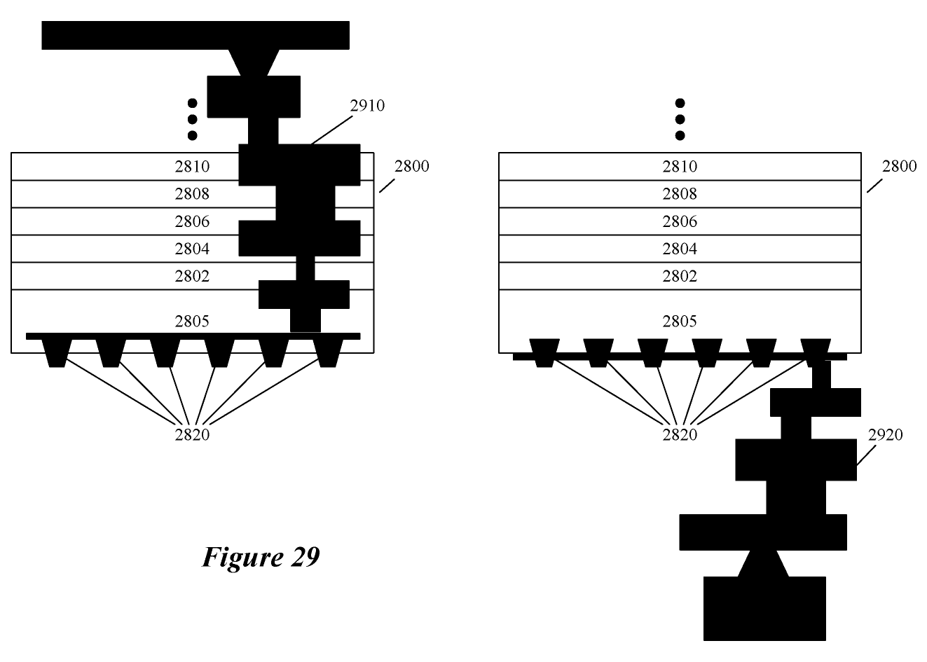

To deliver power to buried power rails (e.g., to power transistors defined on the substrate of the IC), there are two typical methods. The first is frontside power delivery (FSPD), which delivers power from the top of the metal layers and down to the substrate. The second is backside power delivery (BSPD) which delivers power from the bottom of the IC directly into the substrate. FIG. 29 illustrates these two power deliver methods used on the IC 2800. As shown, FSPD 2910 runs from the top of the IC 2800, through the metal layers 2802-2810, and into the substrate 2805 to reach the buried power rails 2820. Alternatively, BSPD 2930 comes from the bottom of the IC 2800 directly to the buried power rails 2820 in the substrate 2805.

FSPD 2910 needs space on each of the metal layers 2802-2810 to reach the buried power rails 2820, which reduces the space available for wiring on all of the metal layers 2802-2810. BSPD 2920, on the other hand, does not take any space on any of the metal layers 2802-2810. Hence, while both methods of power delivery have buried power rails 2820, which increases the kinds of routes (e.g., directions of routes, number of routes) that can be made for wiring on the lower metal layers 2802-2804, BSPD 2920 further does so because it does not take up any space in any of the metal layers 2802-2810. This increases the connection density of the metal layers 2802-2804 even further when using finer-pitch lower metal layers and performing NPD routing, which can decrease the number of metal layers needed for an IC and greatly save on costs.

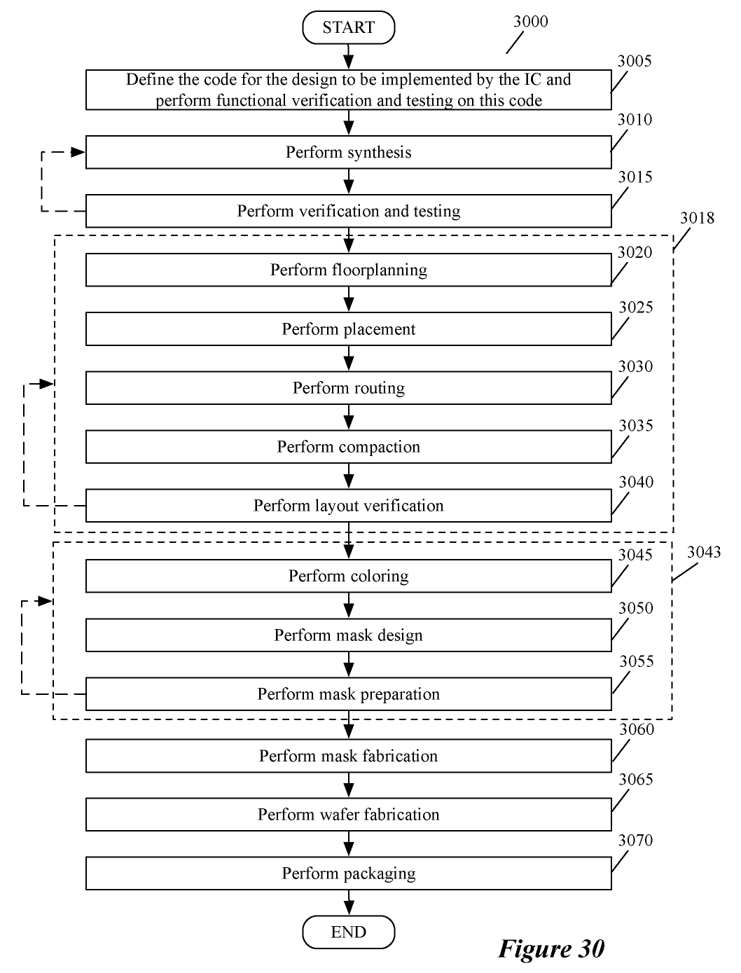

The above-described routing operations are one step or a set of steps in the overall process to design and manufacture an IC. FIG. 30 conceptually illustrates an example of one such process for designing and manufacturing an IC. The process 3000 of this figure defines routes on one or more lower NPD interconnect layers and routes on one or more upper PD interconnect layers during IC design layout generation in order to decrease the number of upper PD layers needed for the IC design layout and to decrease the overall number of interconnect layers needed for the IC design layout, both of which saves on costs when manufacturing an IC from such an IC design layout.

The process 3000 begins (at 3005) by defining the code that specifies the IC design and performing functional verification and testing on this code. In some embodiments, the process uses one of the common hardware description languages (HDL) to specify the code. The HDL code in some embodiments describes the desired structure, behavior, and timing of the IC. To perform functional verification and testing on the code for the IC, some embodiments specify one or more modules and/or circuit components in the code and check the specified modules and/or circuit components for functional accuracy.

Next, the process 3000 performs (at 3010) a synthesis operation, which converts the HDL description into a circuit representation that commonly includes digital circuit components, such as logic gates, flip-flops, and other larger digital components (e.g., adders, multipliers, etc.). The synthesis operation is typically performed by a synthesis tool.

At 3015, the process 3000 performs verification and testing on the circuit representation that is produced by the synthesis operation. In some embodiments, the verification and testing checks the circuit representation to determine whether this representation meets desired timing constraints and satisfies any other constraint of the HDL code. When the verification and testing fails (e.g., if a portion of the circuit representation fails to meet a constraint), the process 3000 returns to step 3010 (as denoted by a dashed arrow line) to reperform synthesis to modify the circuit representation to resolve this failure.

When the verification and testing at 3015 passes, the process 3000 performs a set of physical design operations 3018, which include operations 3020-3035 between which the process 3000 can iterate through multiple times as further described below. At 3020, the process 3000 performs a floorplanning operation that defines a general location for some or all of the circuit blocks (e.g., for various large circuit blocks). For instance, in some embodiments, floorplanning divides the design layout into one or more sections devoted to different purposes (e.g., ALU, memory, decoding, etc.) and assigns some or all of the circuit blocks to these sections based on the purposes served by these blocks.

At 3025, the process 3000 performs a placement operation, which is based on the floorplanning data and defines a specific location and orientation in the design layout for each circuit block. The placement operation in some embodiments is an automated process that tries to find an optimal placement for each circuit block based on one or more optimization criteria, such as congestion or estimated length of interconnects (e.g., metal wires) needed for connecting the nets associated with the circuit blocks. A net in some embodiments includes a set of two or more pins of one or more circuit blocks that need to be connected electrically (e.g., through a set of wires, contacts, and/or vias). After performing the placement operation, the process 3000 might return to the floorplanning operation if it determines that the floorplanning should be revised to improve the result of the placement operation.

Once the placement operation is completed satisfactorily, the process performs (at 3030) a routing operation to define the route needed to connect each net (i.e., to connect each set of pins that needs to be interconnected). Each defined route includes one or more interconnect segments (also called wire segments) that traverse one or more interconnect layers (also called wiring layers), and one or more vias and/or contacts that connect pins and/or wire segments on different wiring layers.

To define the routes, some embodiments divide the routing operation into a global routing operation and a detailed routing operation. For each net, global routing defines a global route that more generally defines the route for the net (e.g., defines a general area in the design layout traversed by the route). For instance, in some embodiments, the global router divides an IC into individual global routing areas, called Gcells. Then, a global route (Groute) is created for each net by listing the global routing areas (the Gcells) that the Groute for the net should pass through.

The detailed routing defines the actual route for each net (e.g., the route that connects the set of pins that forms the net). As mentioned above, each defined route includes one or more interconnect segments that traverse one or more interconnect layers, and one or more vias and/or contacts that connect pins and/or wire segments on different interconnect layers. In performing its detailed routing operation, the detailed router of some embodiments uses the global router’s Groute data, e.g., by biasing its detail route search for the net to the Groute regions traversed by the Groute defined by the global router.

When performing detailed routing, the process 3000 of some embodiments uses one or more of the above-described NPD and PD routing operations to define routes on lower NPD interconnect layers of the design layout and to define routes on upper PD interconnect layers of the design layout. One example of such routing is done to route shorter connections (i.e., connections with an estimated wire length less than a particular threshold) as routes on lower NPD interconnect layers and to route longer connections (i.e., connections with an estimated wire lengths more than the particular threshold) as routes on upper PD interconnect layers. As some embodiments will manufacture lower wiring layers corresponding to the lower interconnect layers using a more-advanced lithographic technology (which produces thinner wires with higher resistance), such embodiments ensure that routes defined on the lower interconnect layers will not lead to high-resistance wires by only defining shorter routes on these layers.

During or after the detailed routing operation, the process 3000 performs a design rule check (DRC) operation to ensure that the defined routes do not violate design rules. One example of the design rule check that is done for a route is to ensure that the route is not closer than an acceptable minimum spacing requirement on each layer traversed by the route to another route or another component in the design layout on that layer. Routes that violate minimum spacing constraints can cause undue capacitance and, in some cases, electrical shorts on the IC.

The process 3000 in some embodiments can iterate through the global and detailed routing multiple times to identify better Groutes for some nets in order to improve the detailed routes for these nets or other nets. Also, the process 3000 in some embodiments can return from either of these routing operations to an earlier operation in the EDA flow (e.g., to the placement operation) in order to improve the results of this earlier operation to improve the routes defined by the later routing operation.

After routing, the process 3000 performs (at 3035) compaction operations. In some embodiments, the compaction operation compresses the design layout in one or more directions to decrease the size of the IC die (e.g., to decrease the two-dimensional area of the IC die) that would be manufactured based on the design layout. Reducing the size of the IC improves the performance of the IC in some embodiments. A compacted design layout also lowers costs of the ICs manufactured using the design layout by allowing more ICs to be produced for a given wafer size.

After the compaction operation, the process 3000 performs a layout verification operation (at 3040) to ensure that the compacted design layout (e.g., the compacted routes in this design) to ensure that the layout meets one or more verification criteria. This verification operation includes a DRC operation that ensures that the compacted design layout does not violate design rules. One example of the DRC that is done for a route is to ensure that the route is not closer than an acceptable minimum spacing requirement on each layer traversed by the route to another route or another component in the design layout on that layer. Other examples of the DRC include ensuring that items in the design layout (e.g., routes, pins, contacts, vias, or other components) do not violate minimum area, minimum width, and maximum curvature requirements.

The layout verification in some embodiments includes other operations, such as extraction. Extraction in some embodiments computes parasitic values (e.g., parasitic capacitance values or parasitic inductance values) exerted on items (e.g., wire segments) in the design layout. In some embodiments, the extraction operation computes capacitance coefficients for one or more conductive components in the design layout (e.g., for each wire segment of a route, or for the entirety of each route, in the design layout), and uses the capacitance coefficients to compute parasitic influence (e.g., capacitance, resistance, or inductance) on the conductive component(s).

After the compaction operation at 3035 or the subsequent verification operation 3040, the process 3000 in some embodiments can return to an earlier operation in the EDA flow (e.g., to the placement operation, to the global routing operation, or to the detailed routing operation) in order to improve the results of this earlier operation to improve the compacted design defined by the later compaction operation. For instance, when the design is not verified at 3040 (e.g., if a problem with the design is detected during verification), the process 3000 returns to an earlier physical design operation 3020 to 3035 to reperform this physical design operation, and any subsequent physical design operation, for a portion or for the entire design layout. In some embodiments, the design layout that exists after the compaction operation and that passes the subsequent verification operation 3040 on this layout is the end result of the physical design process, is called the physical design layout, and is used as the input to the subsequent operations 3045-3055 that form the manufacturing sub-process of the process 3000.

In some embodiments, the physical design sub-process includes other operations that are not displayed in FIG. 30. These other operations are not displayed for purposes of brevity. Examples of such operations include partitioning, power planning, and clock tree synthesis (CTS). In some embodiments, partitioning divides the design layout into similar-sized subsets and ensures a minimum number of connections between subsections. Power planning defines the power delivery network (PDN) that includes the interconnects for delivery power from the power supply circuit to circuits defined by the IC design layout. CTS in some embodiments defines a clock delivery network for delivering one or more clock signals to circuits defined by the IC design layout. CTS in some embodiments also inserts buffers and/or inverters along the clock signal paths on the clock delivery network in order to balance the load and decrease or eliminate any clock skew or delay.

Once physical design operations 3018 are completed and the design layout is finalized, the process 3000 performs a set of mask production operations 3043, which include operations 3045-3060. These processes collectively produce a set of one or more masks for each layer of the IC based on the design layout which, when used to fabricate the IC, should result in an IC (or multiple ICs) that match the design layout as closely as possible.

At 3045, the process 3000 performs a coloring operation for each layer of the design layout. The coloring operation decomposes the design layout for a layer into multiple (e.g., two, three, etc.) separate layouts for the purpose of mask production by assigning each feature in the layout to one of multiple “colors”. For certain IC design layers, the features (e.g., the routes, pins, contacts, vias, etc.) are packed too closely for the features to be printed on a wafer using a single mask. In some embodiments, the coloring operation identifies an optimal decomposition for a layer by iteratively assigning the features in the layer to different colors (e.g., using a graph coloring algorithm) and scoring the decomposition. In some embodiments, this coloring operation is optional and can be skipped for some or all of the IC layers.

After the coloring operation, the process 3000 performs mask design (at 3050) or mask layout generation. Mask design generates, for each layer of the IC, the layout for one or more masks (i.e., one mask for each color) that will optimally create the shapes defined in the layout during fabrication of the IC. Some embodiments use commonly known techniques, such as OPC (optical proximity correction) and/or ILT (inverse lithography technology) operations. An ILT system, for instance, iteratively defines a potential mask layout, performs lithography simulation to simulate the wafer shapes that would be manufactured using the potential mask layout, compares this simulation to a set of target wafer shapes, and updates the mask layout based on the comparison (the inverse lithography step). After numerous such iterations, the ILT system determines an optimized mask design for a given layout.

During or after the mask design operation, the process 3000 performs a mask rule check (MRC) operation (not shown separately in the figure) to ensure that the shapes defined in the mask layout do not violate MRC rules. Examples of the MRC rules include minimum spacing, minimum width, maximum curvature, and minimum area for shapes in the mask layout.

The process 3000 then performs a mask preparation operation at 3055. In some embodiments, the mask preparation operation 3055 includes operations that prepare a mask writer (e.g., an electron beam mask writer) to fabricate a particular mask based on the mask design, such as mask data preparation (MDP) and Mask Process Correction (MPC). MDP in some embodiments prepares the mask layout for a mask writer. This operation in some embodiments includes “fracturing” the data into trapezoids, rectangles, or triangles.

The MPC operation, in some embodiments, accounts for various physical effects during mask production to “correct” the mask layout such that the fabricated mask will more closely match the mask layout. Because of these physical effects, a mask writer following the specific shapes of the mask design will produce a mask that does not perfectly match that mask design. MPC in some embodiments either geometrically modifies these shapes and/or modifies pixel doses for a mask writer such that the resulting mask shapes will more accurately match the desired shapes of the mask design. MDP may use as input the generated mask layout or the results of MPC. MPC may be performed as part of a fracturing or other MDP operation. Other corrections may also be performed as part of fracturing or other MDP operations. Also, in some embodiments, the mask preparation operation calculates several possible mask images by using charged particle beam simulation. Additional description of the mask design and mask preparation operations is provided in U.S. Patent No. 8,719,739, entitled “Method and System for Forming Patterns Using Charged Particle Beam Lithography”, which is incorporated herein by reference.

Other embodiments, that do not use MPC to modify the mask shapes or pixel doses for a mask writer in order to produce the desired mask shapes, perform a separate mask simulation operation followed by a wafer simulation operation as a verification of the output of the mask design operation 3050. Mask simulation in this case simulates the production of each mask using the respective generated mask layout, while wafer simulation simulates the resulting wafer shapes based on these simulated masks to verify that the resulting wafer shapes will be close enough to the desired wafer shapes.

In some embodiments, after performing mask preparation and/or simulation (or after performing a mask rule check prior to the mask preparation), the process 3000 can return to an earlier operation in the mask production operations 3043 (e.g., to coloring 3045 or mask design 3050) in order to improve the results of this earlier operation and thereby improve the eventual fabricated mask. Due to the high expenses of fabricating a mask, it is generally desirable to have the mask designs optimized before fabrication. In some embodiments, the process 3000 can iteratively repeat the mask production operations 3043 in order to improve the quality of the overall generated mask or can return to one of the earlier physical design operations 3018.

Once the mask layout is generated and verified, the process 3000 fabricates (at 3060) the one or more masks specified for all the layers of the IC based on the mask layout. Mask generation transforms each mask image (also referred to as a mask layer, in some embodiments) of the mask layout into one or more lithographic masks in some embodiments. In some embodiments, the MPC operation is actually performed within the mask writer as the mask writer fabricates a given mask based on the mask design for that mask (i.e., to modify the mask writer output in order to better produce the desired mask).

Once the masks are generated, the process 3000 performs (at 3065) wafer fabrication, which uses the generated masks to manufacture multiple IC dies on an IC wafer (e.g., a silicon wafer). The masks for the substrate and each wiring layer are used to generate the devices and wiring on the substrate and each wiring layer of each IC die. Each IC die is usually tested. During the testing of the IC dies, if it is determined that the IC has a defect because of its design or its masks, the process 3000 has to return to an earlier operation to improve its design layout, its mask layout, or its mask production operation. Lastly, the process 3000 performs (at 3055) packaging, which places each IC die in one chip package. Packaging in some embodiments includes slicing a wafer into multiple IC dies and placing each die on a substrate, which is then encapsulated to form a chip package. After performing packaging, the process 3000 ends.

Although several embodiments were described above by reference to performing mask layout optimization for IC designs used to design and/or manufacture an IC, one of ordinary skill will realize that other embodiments are used to perform similar mask layout operations for design layouts that are created for designing and manufacturing silicon interposers (e.g., wiring patterns on silicon interposers).

Still other embodiments are used to design and manufacture other patterns on other types of substrates. For instance, some embodiments use the above-described mask layout optimization processes to design masks for design layouts for designing displays such as flat-panel displays (e.g., monitors, televisions, glasses, etc.) or curved displays (e.g., displays for virtual reality or augmented reality headsets). Such design layouts define patterns of controllable pixels on a display substrate. Still other embodiments use the above-described tile-based parasitic extraction processes to check the design layouts for designing other patterns of other elements for other substrates. Examples of such other substrates include substrates used to manufacture micro-electromechanical (MEMS) and other such similar devices.

Many of the above-described features and applications are implemented as software processes that are specified as a set of instructions recorded on a computer readable storage medium (also referred to as computer readable medium). When these instructions are executed by one or more processing unit(s) (e.g., one or more processors, cores of processors, or other processing units), they cause the processing unit(s) to perform the actions indicated in the instructions. Examples of computer readable media include, but are not limited to, CD-ROMs, flash drives, RAM chips, hard drives, EPROMs, etc. The computer readable media does not include carrier waves and electronic signals passing wirelessly or over wired connections.

In this specification, the term “software” is meant to include firmware residing in read-only memory or applications stored in magnetic storage, which can be read into memory for processing by a processor. Also, in some embodiments, multiple software inventions can be implemented as sub-parts of a larger program while remaining distinct software inventions. In some embodiments, multiple software inventions can also be implemented as separate programs. Finally, any combination of separate programs that together implement a software invention described here is within the scope of the invention. In some embodiments, the software programs, when installed to operate on one or more electronic systems, define one or more specific machine implementations that execute and perform the operations of the software programs.

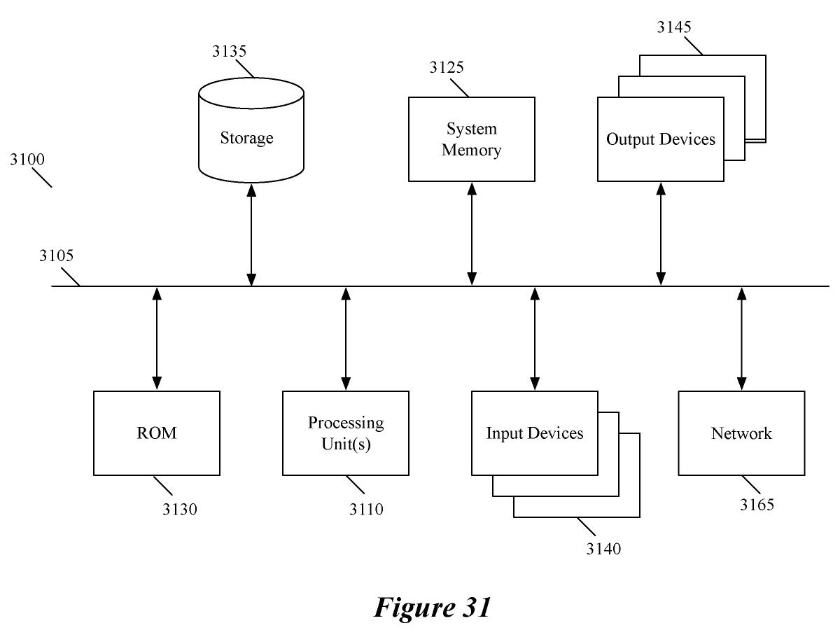

FIG. 31 conceptually illustrates a computer system 3100 with which some embodiments of the invention are implemented. The computer system 3100 can be used to implement any of the above-described computers and servers. As such, it can be used to execute any of the above-described processes. This computer system includes various types of non-transitory machine-readable media and interfaces for various other types of machine-readable media. Computer system 3100 includes a bus 3105, processing unit(s) 3110, a system memory 3125, a read-only memory 3130, a permanent storage device 3135, input devices 3140, and output devices 3145.

The bus 3105 collectively represents all system, peripheral, and chipset buses that communicatively connect the numerous internal devices of the computer system 3100. For instance, the bus 3105 communicatively connects the processing unit(s) 3110 with the read-only memory 3130, the system memory 3125, and the permanent storage device 3135.

From these various memory units, the processing unit(s) 3110 retrieve instructions to execute and data to process in order to execute the processes of the invention. The processing unit(s) may be a single processor or a multi-core processor in different embodiments. The read-only-memory (ROM) 3130 stores static data and instructions that are needed by the processing unit(s) 3110 and other modules of the computer system. The permanent storage device 3135, on the other hand, is a read-and-write memory device. This device is a non-volatile memory unit that stores instructions and data even when the computer system 3100 is off. Some embodiments of the invention use a mass-storage device (such as a magnetic or optical disk and its corresponding disk drive) as the permanent storage device 3135.

Other embodiments use a removable storage device (such as a flash drive, etc.) as the permanent storage device. Like the permanent storage device 3135, the system memory 3125 is a read-and-write memory device. However, unlike storage device 3135, the system memory is a volatile read-and-write memory, such a random-access memory. The system memory stores some of the instructions and data that the processor needs at runtime. In some embodiments, the invention’s processes are stored in the system memory 3125, the permanent storage device 3135, and/or the read-only memory 3130. From these various memory units, the processing unit(s) 3110 retrieve instructions to execute and data to process in order to execute the processes of some embodiments.

The bus 3105 also connects to the input and output devices 3140 and 3145. The input devices enable the user to communicate information and select commands to the computer system. The input devices 3140 include alphanumeric keyboards and pointing devices (also called “cursor control devices”). The output devices 3145 display images generated by the computer system. The output devices include printers and display devices, such as cathode ray tubes (CRT) or liquid crystal displays (LCD). Some embodiments include devices such as a touchscreen that function as both input and output devices.

Finally, as shown in FIG. 31, bus 3105 also couples computer system 3100 to a network 3165 through a network adapter (not shown). In this manner, the computer can be a part of a network of computers (such as a local area network (“LAN”), a wide area network (“WAN”), or an Intranet, or a network of networks, such as the Internet. Any or all components of computer system 3100 may be used in conjunction with the invention.

Some embodiments include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, read-only and recordable Blu-Ray® discs, ultra-density optical discs, and any other optical or magnetic media. The computer-readable media may store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

While the above discussion primarily refers to microprocessor or multi-core processors that execute software, some embodiments are performed by one or more integrated circuits, such as application specific integrated circuits (ASICs) or field programmable gate arrays (FPGAs). In some embodiments, such integrated circuits execute instructions that are stored on the circuit itself.

As used in this specification, the terms “computer”, “server”, “processor”, and “memory” all refer to electronic or other technological devices. These terms exclude people or groups of people. For the purposes of the specification, the terms display or displaying means displaying on an electronic device. As used in this specification, the terms “computer readable medium,” “computer readable media,” and “machine readable medium” are entirely restricted to tangible, physical objects that store information in a form that is readable by a computer. These terms exclude any wireless signals, wired download signals, and any other ephemeral or transitory signals.

While the invention has been described with reference to numerous specific details, one of ordinary skill in the art will recognize that the invention can be embodied in other specific forms without departing from the spirit of the invention. Thus, one of ordinary skill in the art would understand that the invention is not to be limited by the foregoing illustrative details but rather is to be defined by the appended claims.

1. A method of manufacturing an integrated circuit (IC) wafer with a first set of non-preferred direction (NPD) wiring layers and a second set of preferred direction (PD) wiring layers above the first set of wiring layers, the method comprising:
using a first type of lithographic technology to manufacture wiring on the first set of NPD wiring layers, wherein each particular layer in the first set of NPD wiring layers is an NPD wiring layer as the particular layer does not have a single preferred direction (PD) for more than 50% of the wiring on the particular layer; and
using a second type of lithographic technology that is less advanced than the first type of lithographic technology to manufacture wiring on the second set of PD wiring layers above the first set of NPD wiring layers, wherein each particular layer in the second set of PD wiring layers is a PD wiring layer as more than 50% of the wiring on the particular layer is along a single PD of the particular layer.

2. The method of claim 1, wherein the first type of lithographic technology is more advanced than the second type of lithographic technology and is able to produce a first feature size that is smaller than a second feature size produced by the second type of lithographic technology.

3. The method of claim 2, wherein the first and second feature sizes are first and second sizes of first and second components on the IC wafer.

4. The method of claim 3, wherein the first and second feature sizes are one of a minimum gate width, a minimum wire width, or a minimum transistor width.

5. The method of claim 2, wherein the first type of lithographic technology is able to produce smaller circuit components due to the smaller first feature size.

6. The method of claim 5, wherein the smaller circuit components include at least one of transistors, diodes, capacitors, and resistors.

7. The method of claim 1, wherein a first set of lithographic machines is used for the first type of lithographic technology, and a second set of lithographic machines is used for the second type of lithographic technology.

8. The method of claim 7, wherein using the first type of lithographic technology to manufacture wiring on the first set of NPD wiring layers comprises also using one or more other advanced technologies to manufacture the wiring on the first set of NPD wiring layers.

9. The method of claim 8, wherein the one or more other advanced lithographic technologies comprises a more advanced etching technology.

10. The method of claim 7, wherein the first set of lithographic machines is a set of Extreme Ultraviolet (EUV) lithographic machines, and the second set is a set of non-EUV lithographic machines.

11. The method of claim 10, wherein the second set of lithographic machines is a set of 193 nanometer immersion (193i) lithographic machines.

12. The method of claim 1, wherein each PD is a horizontal direction or a vertical direction, and the PDs of different adjacent layers in the second set of PD wiring layers alternate between horizontal and vertical directions.

13. The method of claim 12, wherein, on each particular layer in the second set of PD wiring layers, more than 90% of the wiring on the particular layer is along the single PD of the particular layer.

14. The method of claim 1, wherein the first set of NPD wiring layers comprises layers 3 and 4, and the second set of PD wiring layers comprises layers 5 and 6.

15. The method of claim 1, wherein the first set of NPD wiring layers comprises layers 3, 4 and 5, and the second set of PD wiring layers comprises layers 6 and 7.

16. The method of claim 1, wherein the first set of NPD wiring layers comprises layers 2 and 3, and the second set of PD wiring layers comprises layers 4 and 5.

17. The method of claim 1, wherein the first set of NPD wiring layers comprises layers 2, 3 and 4, and the second set of PD wiring layers comprises layers 5 and 6.

18. The method of claim 1, wherein the IC wafer further includes a third set of wiring layers below the first set of NPD wiring layers, the method further comprising using the second type of lithographic technology to manufacture wiring on the third set of wiring layers for regions on each particular layer in the third set of wiring layers that has a single PD of the regions on the particular layer.

19. The method of claim 18, wherein the regions on each particular layer in the third set of wiring layers are used for wiring associated with standard cells and circuit blocks.

20. The method of claim 18 further comprising using the first type of lithographic technology to manufacture wiring on the third set of wiring layers in areas between the regions on each particular layer in the third set of wiring layers.

21. The method of claim 20, wherein the third set of wiring layers comprises layers 1, 2 and 3.

22. The method of claim 20, wherein the first set of NPD wiring layers comprises layers 3 and 4, and the third set of wiring layers comprises layers 1 and 2.

23. The method of claim 22, wherein the second set of PD wiring layers comprises at least one of layers 5 and 6.
